(19) United States
(12) Patent Application Publication
(10) Pub. No.: US 2002/0037084 A1
(43) Pub. Date: Mar. 28, 2002

(54) Singnal processing device and recording medium

(76) Inventors: Isao Kakuhari, Nara (JP); Kenichi Terai, Osaka (JP); Hiroyuki Hashimoto, Osaka (JP)

Correspondence Address: SNELL & WILMER, ONE ARIZONA CENTER, 400 EAST VAN BUREN, PHOENIX, AZ, 850040001

(21) Appl. No.: 09/964,191

(22) Filed: Sep. 26, 2001

(30) Foreign Application Priority Data
Sep. 26, 2000 (JP) 2000-293169

(51) Int. Cl. H03G 5/00

(52) U.S. Cl. 381/98

(57) ABSTRACT

A signal processing apparatus for processing an acoustic signal reproduced together with an image signal includes a memory for storing a plurality of filter coefficients for correcting the acoustic signal; a filter coefficient selection section for receiving a correction command for specifying a correction method for the acoustic signal from outside the signal processing apparatus and selecting at least one of the plurality of filter coefficients stored in the memory based on the correction command; and a correction section for correcting the acoustic signal using the at least one filter coefficient selected by the filter coefficient selection section.

### BACKGROUND OF THE INVENTION

1. Field of the Invention

The present invention relates to a signal processing apparatus for processing an acoustic signal reproduced together with an image signal and a recording medium, and specifically to a signal processing signal for providing a viewer/listener with a perception of distance of an acoustic image matched to the situation represented by an image signal reproduced and thus realizing a viewing and listening environment in which image data and acoustic data match each other, and a recording medium having such image data and acoustic data recorded thereon.

2. Description of the Related Art

Recently, optical disks such as laser disks and DVDs (digital versatile disks) have been widely used as recording media for storing acoustic data together with image data, in addition to video tapes. More and more households are now provided with an environment for allowing people to easily enjoy an audio and visual experience, using laser disk players and DVD players for reproducing data stored in the laser disks and DVDs. In addition, standards such as MPEG allows acoustic data and image data to be compressed together, so that individual viewers/listeners can enjoy audio and video reproduction on a personal computer.

In general, under such a reproduction environment, however, the image data and the acoustic data are not sufficiently matched together. For example, while an image changes from a short range view to a distant view or pans outs to the left or to the right, an acoustic image is fixed at a certain position.

In order to solve such a problem and thus provide the viewer/listener with an improved environment of viewing and listening reproduction of image data and acoustic data, various proposals have been made.

For example, Japanese Laid-Open Publication No. 9-70094 discloses a technology for installing a sensor for detecting a motion of the head of a viewer/listener and correcting the acoustic signal based on an output signal from the sensor, so as to change the position of the acoustic image to match the motion of the head of the viewer/listener.

International Publication WO95/22235 discloses a technology for installing a sensor for detecting a motion of the head of a viewer/listener and performing sound source localization control in synchronization with the video.

However, conventional signal processing apparatuses using the above-described technologies can only use a filter prepared in the signal processing apparatuses in order to correct the acoustic signal. Therefore, it is impossible to correct the acoustic signal as desired by the viewer/listener or to reflect the intent of the content producer to correct the acoustic signal.

Even when a filter for correcting the acoustic signal as desired by the viewer/listener is prepared, the acoustic signal used needs to be corrected by a personal computer or the like. Therefore, in order to guarantee the matching of the image data and the acoustic data, extensive work is required.

A plurality of signal processing methods have been proposed for realizing movement of an acoustic image on a monitor screen for displaying an image. No signal processing method for providing the viewer/listener with a perception of distance of an acoustic image (depth of the acoustic image) with a small memory capacity and a small calculation amount has been proposed.

### SUMMARY OF THE INVENTION

According to one aspect of the invention, a signal processing apparatus for processing an acoustic signal reproduced together with an image signal includes a memory for storing a plurality of filter coefficients for correcting the acoustic signal; a filter coefficient selection section for receiving a correction command, from outside the signal processing apparatus, for specifying a correction method for the acoustic signal and selecting at least one of the plurality of filter coefficients stored in the memory based on the correction command; and a correction section for correcting the acoustic signal using the at least one filter coefficient selected by the filter coefficient selection section.

Due to such a structure, a signal processing apparatus according to the present invention allows the correction method of an acoustic signal to be changed in accordance with the change in an image signal or an acoustic signal. Thus, the viewer/listener can receive, through a speaker or headphones, a sound matching an image being displayed by an image display apparatus. As a result, the viewer/listener does not notice any discrepancies in a relationship between the image and the sound.

Also due to such a structure, a signal processing apparatus according to the present invention allows the correction method of an acoustic signal to be changed in accordance with the acoustic characteristic of the speaker or the headphones used by the viewer/listener or the acoustic characteristic based on the individual body features, for example, the shape of the ears and the face of the viewer/listener. As a result, a more favorable listening environment can be provided to the viewer/listener.

Since the filter coefficients are stored in the memory, it is not necessary to receive the filter coefficients from outside the signal processing apparatus while the image signal and the acoustic signal are being reproduced. Accordingly, when the signal processing apparatus receives a correction command, the filter coefficients can be switched more frequently in accordance with the change in the image signal and the acoustic signal. As a result, the correction method for the acoustic signal can be changed while reflecting the intent of the producer of the image signal and the acoustic signal (contents).

In one embodiment of the invention, the correction command is input to the signal processing apparatus by receiving of a broadcast signal or a communication signal.

In one embodiment of the invention, the correction command is recorded on a recording medium and is input to the signal processing apparatus by reproduction of the recording medium.

Due to such a structure, the correction command can be input to the signal processing apparatus by reproducing the data recorded on the recording medium.

In one embodiment of the invention, the memory is arranged so as to receive at least one filter coefficient for correcting the acoustic signal from outside the signal processing apparatus, and to add the at least one filter coefficient received to the plurality of filter coefficients stored in the memory or to replace at least one of the plurality of filter coefficients stored in the memory with the at least one filter coefficient received.

Due to such a structure, the content of the filter coefficients stored in the memory can be easily updated.

In one embodiment of the invention, the at least one filter coefficient received is recorded on a recording medium and is input to the signal processing apparatus by reproduction of the recording medium.

Due to such a structure, at least one filter coefficient can be input to the signal processing apparatus by reproducing the data recorded on the recording medium.

In one embodiment of the invention, the signal processing apparatus further includes a buffer memory for temporarily accumulating the image signal and the acoustic signal. A speed at which the image signal and the acoustic signal are input to the buffer memory is higher than a speed at which the image signal and the acoustic signal are output from the buffer memory. The at least one filter coefficient recorded on the recording medium is stored in the memory while the image signal and the acoustic signal are output from the buffer memory. A time period required for the image signal and the acoustic signal to be output from the buffer memory is equal to or longer than a time period for the at least one filter coefficient to be stored in the memory.

Due to such a structure, acoustic signal correction data recorded on a recording medium can be reproduced without interrupting the image signal or the acoustic signal which is output from the reproduction apparatus.

In one embodiment of the invention, the at least one filter coefficient selected includes at least one filter coefficient representing a transfer function showing an acoustic characteristic of a direct sound from a sound source to a viewer/listener. The correction section includes a transfer function correction circuit for correcting a transfer function of the acoustic signal in accordance with the at least one filter coefficient representing the transfer function.

Due to such a structure, the viewer/listener can perceive the virtual sound source using the speaker or the headphones.

In one embodiment of the invention, the at least one filter coefficient selected includes at least one filter coefficient representing a transfer function showing an acoustic characteristic of a direct sound from a sound source to a viewer/listener and at least one filter coefficient representing a reflection structure showing an acoustic characteristic of a reflection from the sound source to the viewer/listener. The correction section includes a transfer function correction circuit for correcting the transfer function of the acoustic signal in accordance with the at least one filter coefficient representing the transfer function, a reflection addition circuit for adding a reflection to the acoustic signal in accordance with the at least one filter coefficient representing the reflection structure, and an adder for adding an output from the transfer function correction circuit and an output from the reflection addition circuit.

Due to such a structure, the viewer/listener can perceive the virtual sound source using the speaker or the headphones and requiring only a smaller calculation amount.

In one embodiment of the invention, the at least one filter coefficient selected includes at least one filter coefficient representing a transfer function showing an acoustic characteristic of a direct sound from a sound source to a viewer/listener and at least one filter coefficient representing a reflection structure showing an acoustic characteristic of a reflection from the sound source to the viewer/listener. The correction section includes a transfer function correction circuit for correcting the transfer function of the acoustic signal in accordance with the at least one filter coefficient representing the transfer function, and a reflection addition circuit for adding a reflection to an output of the transfer function correction circuit in accordance with the at least one filter coefficient representing the reflection structure.

Due to such a structure, the viewer/listener can more clearly perceive the virtual sound source using the speaker or the headphones and using a smaller calculation amount.

In one embodiment of the invention, the filter coefficient selection section includes an automatic selection section for automatically selecting at least one of the plurality of filter coefficients stored in the memory based on the correction command, and a manual selection section for manually selecting at least one of the plurality of filter coefficients stored in the memory.

Due to such a structure, the viewer/listener can select automatic selection of a filter coefficient or manual selection of a filter coefficient.

In one embodiment of the invention, the at least one filter coefficient representing the reflection structure includes a first filter coefficient representing a reflection structure showing an acoustic characteristic of a reflection from the sound source to the viewer/listener when a distance between the sound source and the viewer/listener is a first distance, and a second filter coefficient representing a reflection structure showing an acoustic characteristic of a reflection from the sound source to the viewer/listener when the distance between the sound source and the viewer/listener is a second distance which is different from the first distance.

Due to such a structure, the distance between the virtual sound source and the viewer/listener can be arbitrarily set.

In one embodiment of the invention, the at least one filter coefficient representing the reflection structure includes a third filter coefficient representing a reflection structure showing an acoustic characteristic of a reflection reaching the viewer/listener from a direction in a predetermined range.

Due to such a structure, the sound field desired by the viewer/listener can be provided at a higher level of precision.

In one embodiment of the invention, the predetermined range is defined by a first straight line connecting the sound source and a center of a head of the viewer/listener and a second straight line extending from the center of the head of the viewer/listener at an angle of 15 degrees or less from the first straight line.

Due to such a structure, the sound field desired by the viewer/listener can be provided at a higher level of precision.

In one embodiment of the invention, the acoustic signal includes multiple-channel acoustic signals, and the filter coefficient selection section selects a filter coefficient corresponding to each of the multiple-channel acoustic signals.

Due to such a structure, the location of the virtual sound source desired by the viewer/listener can be realized.

In one embodiment of the invention, the signal processing apparatus further includes a display section for displaying a distance between a sound source and a viewer/listener.

Due to such a structure, the viewer/listener can visually perceive the distance between the virtual sound source and the viewer/listener.

According to another aspect of the invention, a recording medium includes an acoustic data area for storing an acoustic signal; an image data area for storing an image signal; a navigation data area for storing navigation data showing locations of the acoustic data area and the image data area; and an assisting data area for storing assisting data. Acoustic signal correction data is stored in at least one of the acoustic data area, the image data area, the navigation data area, and the assisting data area. The acoustic signal correction data includes at least one of a correction command for specifying a correction method for the acoustic signal and a filter coefficient for correcting the acoustic signal.

Due to such a structure, the acoustic signal can be corrected in association with reproduction of an image signal or an acoustic signal stored on the recording medium.

In one embodiment of the invention, the correction command is stored in at least one of the acoustic data area, the image data area, and the navigation data area, and the filter coefficient is stored in the assisting data area.

Due to such a structure, reproduction of the image signal, the acoustic signal or the navigation data is prevented from being interrupted by reproduction of a filter coefficient requiring a larger capacity than the correction command.

In one embodiment of the invention, the image data area stores at least one image pack, and the image pack includes the image signal and the acoustic signal correction data.

Due to such a structure, the correction method for the acoustic signal can be changed in accordance with the change in the image signal.

In one embodiment of the invention, the acoustic data area stores at least one acoustic pack, and the acoustic pack includes the acoustic signal and the acoustic signal correction data.

Due to such a structure, the correction method for the acoustic signal can be changed in accordance with the change in the acoustic signal.

In one embodiment of the invention, the navigation data area stores at least one navigation pack, and the navigation pack includes the navigation data and the acoustic signal correction data.

Due to such a structure, the correction method for the acoustic signal can be changed in accordance with the change in the image signal or the acoustic signal which changes based on the navigation data.

Thus, the invention described herein makes possible the advantages of providing a signal processing apparatus of an acoustic signal for reproducing an image signal and an acoustic signal while fulfilling various requests from viewers/listeners, and a recording medium having such an image signal and an acoustic signal recorded thereon.

These and other advantages of the present invention will become apparent to those skilled in the art upon reading and understanding the following detailed description with reference to the accompanying figures.

### BRIEF DESCRIPTION OF THE DRAWINGS

FIG. 1A is a block diagram illustrating a structure of a signal processing apparatus 1a according to one example of the present invention;

FIG. 1B is a block diagram illustrating another form of using the signal processing apparatus 1a according to the example of the present invention;

FIG. 1C is a block diagram illustrating still another form of using the signal processing apparatus 1a according to the example of the present invention;

FIG. 2 shows an example of a logic format of a DVD 1;

FIG. 3 shows an example of a logic format of a still picture data area 14 shown in FIG. 2;

FIG. 4 shows an example of a logic format of an acoustic data area 15 shown in FIG. 2;

FIG. 5 shows another example of the logic format of the DVD 1;

FIG. 6 shows-an example of a logic format of an image/acoustic data area 54 shown in FIG. 5;

FIG. 7 shows an example of a correction command and a filter coefficient;

FIG. 8A shows a state in which a signal recorded on the DVD 1 is reproduced;

FIG. 8B shows a state in which a signal recorded on the DVD 1 is reproduced;

FIG. 8C shows a state in which a signal recorded on the DVD 1 is reproduced;

FIG. 9A shows a state in which a signal recorded on the DVD 1 is reproduced;

FIG. 9B shows a state in which a signal recorded on the DVD 1 is reproduced;

FIG. 9C shows a state in which a signal recorded on the DVD 1 is reproduced;

FIG. 10A is a block diagram illustrating an exemplary structure of a correction section 5;

FIG. 10B is a block diagram illustrating another exemplary structure of the correction section 5;

FIG. 10C is a block diagram illustrating still another exemplary structure of the correction section 5;

FIG. 11 is a plan view of a sound field 94;

FIG. 12 is a block diagram illustrating an exemplary structure of a transfer function correction circuit 91;

FIG. 13 is a block diagram illustrating another exemplary structure of the transfer function correction circuit 91;

FIG. 14 is a block diagram illustrating an exemplary structure of a reflection addition circuit 92;

FIG. 15 is a block diagram illustrating another exemplary structure of the reflection addition circuit 92;

FIG. 16 is a block diagram illustrating still another exemplary structure of the reflection addition circuit 92;

FIG. 17 is a block diagram illustrating still another exemplary structure of the reflection addition circuit 92;

FIG. 18 is a block diagram illustrating an exemplary structure of a filter coefficient selection section 3:

FIGS. 19A, 19B and 19C show various types of a switch provided in a manual selection section 111;

FIG. 20A is a block diagram illustrating another exemplary structure of the filter coefficient selection section 3;

FIG. 20B is a block diagram illustrating still another exemplary structure of the filter coefficient selection section 3;

FIG. 21A is a plan view of a sound field 122;

FIG. 21B is a side view of the sound field 122;

FIG. 22 shows reflection structures 123a through 123n obtained at the position of the left ear of a viewer/listener 120;

FIG. 23 is a plan view of a sound field 127 in which five sound sources are provided;

FIG. 24 shows reflection structures respectively for directions from which sounds are transferred in areas 126a through 126e in a reflection structure 123a;

FIG. 25 is a block diagram illustrating an exemplary structure of the correction section 5 for reproducing the sound field 122 using reflection structures 128a through 128e;

FIG. 26 is a block diagram illustrating an exemplary structure of the correction section 5 for reproducing the sound field 122 using headphones 6;

FIG. 27 is a plan view of the sound field 127 reproduced by the correction section 5 shown in FIG. 26;

FIG. 28 is a block diagram illustrating an exemplary structure of the correction section 5 in the case where 5.1-ch acoustic signals by Dolby Surround are input to the correction section 5;

FIG. 29 shows an example of an area defining a direction from which a reflection is transferred;

FIG. 30 shows measurement results of head-related transfer functions from a sound source to the right ear of a subject;

FIG. 31 shows measurement results of head-related transfer functions from a sound source to the right ear of a different subject;

FIG. 32A shows another example of an area defining a direction from which a reflection is transferred;

FIG. 32B shows still another example of an area defining a direction from which a reflection is transferred;

FIG. 33 shows reflection structures 133a through 133n;

FIG. 34 is a block diagram illustrating another exemplary structure of the correction section 5 in the case where 5.1-ch acoustic signals of Dolby Surround are input to the correction section 5;

FIG. 35 shows locations of five virtual sound sources 130a through 130e; and

FIG. 36 shows examples of displaying a distance between a virtual sound source and a viewer/listener.

### DESCRIPTION OF THE PREFERRED EMBODIMENTS

Hereinafter, the present invention will be described by way of illustrative examples with reference to the accompanying drawings. The following example are only illustrative and not intended to limit the scope of the present invention. In the following description, a DVD will be described as an example of a recording medium on which an image signal and an acoustic signal are recorded. It should be noted, however, the recording medium used by the present invention is not limited to a DVD. Usable recording media also include any other type of recording media (for example, optical disks other than DVDs and hard disks in the computers). In the following example, an image signal, an acoustic signal, or acoustic signal correction data recorded on a recording medium is reproduced, so as to input the image signal, the acoustic signal, or the acoustic signal correction data to a signal processing apparatus. The present invention is not limited to this. For example, broadcast or communication may be received so as to input an image signal, an acoustic signal or acoustic signal correction data to a signal processing apparatus.

1. Structure of a Signal Processing Apparatus 1a

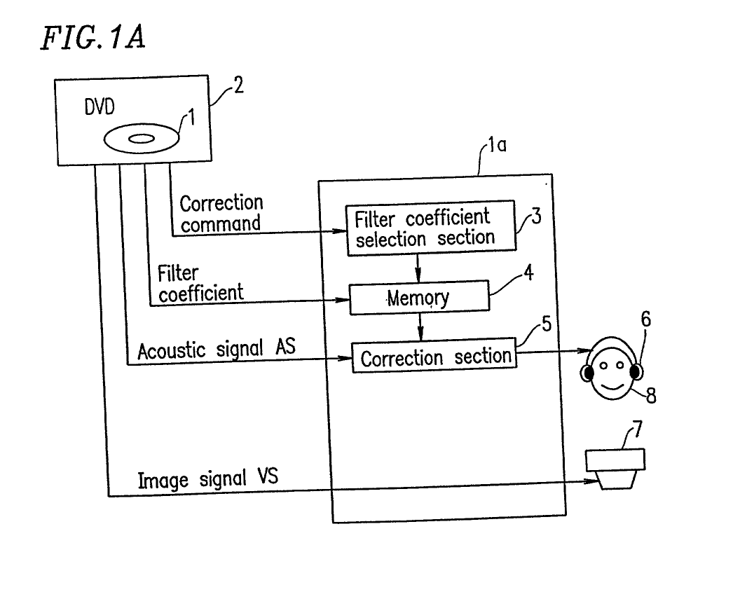

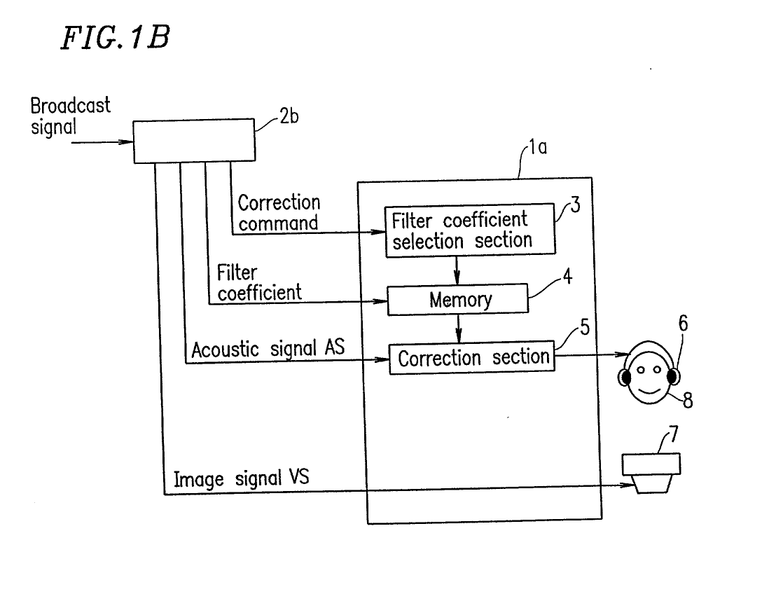

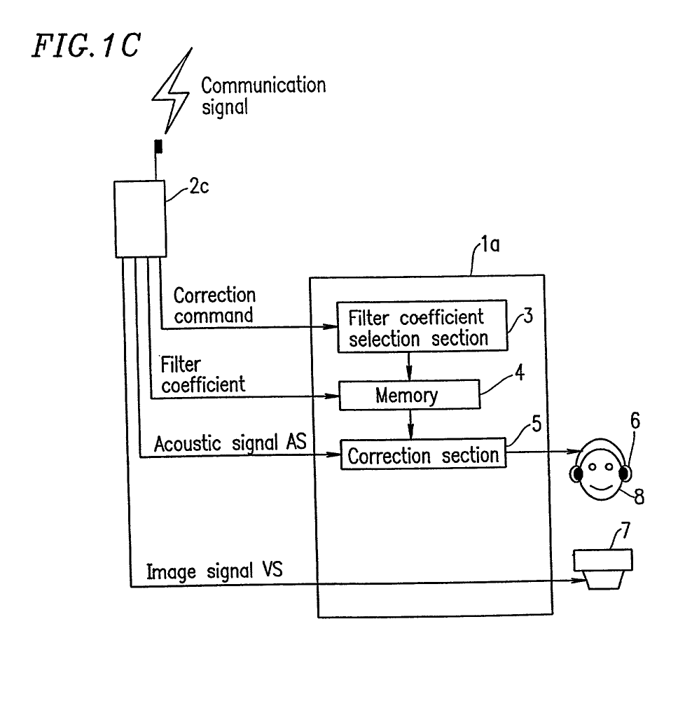

FIG. 1A shows a signal processing apparatus 1a according to an example of the present invention. The signal processing apparatus 1a is connected to a reproduction apparatus 2 for reproducing information recorded on a DVD 1.

The DVD 1 has, for example, an acoustic signal AS, an image signal VS, navigation data, assisting data, and acoustic signal correction data recorded thereon. The acoustic signal correction data includes a correction command for specifying a correction method of the acoustic signal AS, and at least one filter coefficient for correcting the acoustic signal AS. Alternatively, the acoustic signal correction data may include only the correction command or only at least one filter coefficient.

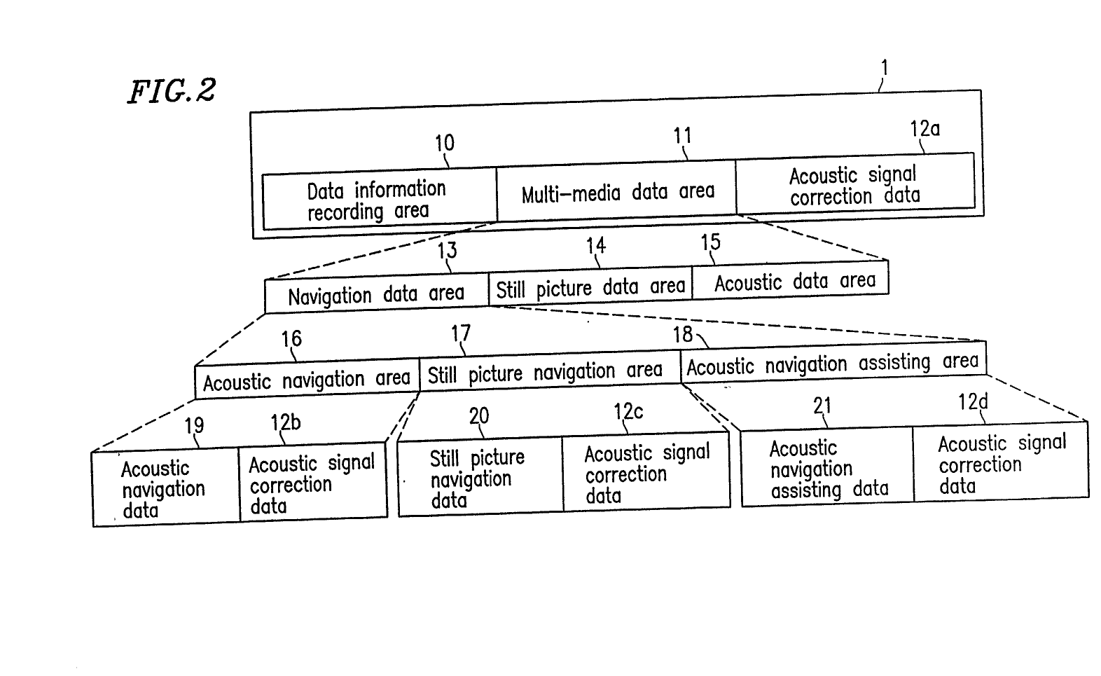

The correction data and the filter coefficient included in the acoustic signal correction data are input to the signal processing apparatus 1a by reproducing the information recorded on the DVD 1 using the reproduction apparatus 2. The format of the DVD 1 will be described in detail below with reference to FIGS. 2 through 6.

The signal processing apparatus 1a includes a memory 4 for storing a plurality of filter coefficients for correcting the acoustic signal AS, a filter coefficient selection section 3 for receiving the correction command from outside the signal processing apparatus 1a and selecting at least one of the plurality of filter coefficients stored in the memory 4 based on the correction command, and a correction section 5 for correcting the acoustic signal AS using the at least one filter coefficient selected by the filter coefficient selection section 3.

The memory 4 is configured to receive at least one filter coefficient for correcting the acoustic signal AS from outside the signal processing apparatus 1a. The at least one filter coefficient input to the memory 4 is added to the plurality of filter coefficients stored in the memory 4. Alternatively, the at least one filter coefficient input to the memory 4 may replace at least one of the plurality of filter coefficients stored in the memory 4.

The acoustic signal AS corrected by the correction section 5 is output to headphones 6. The headphones 6 convert the corrected acoustic signal AS to a sound and outputs the sound. The image signal VS output from the reproduction apparatus 2 is output to an image display apparatus 7 (for example, a TV). The image display apparatus 7 displays an image based on the image signal VS. Reference numeral 8 represents a viewer/listener who views the image displayed on the image display apparatus 7 while wearing the headphones 6.

FIG. 1B shows another form of using the signal processing apparatus 1a according to the example of the present invention. In FIG. 1B, identical elements previously discussed with respect to FIG. 1A bear identical reference numerals and the detailed descriptions thereof will be omitted. In the example shown in FIG. 1B, the signal processing apparatus 1a is connected to a receiver 2b for receiving a broadcast signal. The receiver 2b may be, for example, a set top box.

The broadcast may be, for example, a digital TV broadcast. Alternatively, the broadcast may be a streaming broadcast through an arbitrary network such as, for example, the Internet. An image signal, an acoustic signal or acoustic signal correction data received through such a broadcast may be temporarily accumulated in a recording medium (not shown) such as, for example, a hard disk, and then the accumulated data may be input to the signal processing apparatus 1a.

FIG. 1C shows still another form of using the signal processing apparatus 1a according to the example of the present invention. In FIG. 1C, identical elements previously discussed with respect to FIG. 1A bear identical reference numerals and the detailed descriptions thereof will be omitted. In the example shown in FIG. 1C, the signal processing apparatus 1a is connected to a communication device 2c for receiving a communication signal. The communication device 2c may be, for example, a cellular phone for receiving a communication signal through a wireless communication path. Alternatively, the communication device 2c may be, for example, a modem for receiving a communication signal through a wired communication path. Such a wireless communication path or a wired communication path may be connected to the Internet. The signal processing apparatus 1a may temporarily accumulate an image signal, an acoustic signal or acoustic signal correction data in a recording medium (not shown) such as, for example, a hard disk, and then input the accumulated data to the signal processing apparatus 1a.

Hereinafter, elements of the signal processing apparatus 1a will be described using, as an example, the case where the signal processing apparatus 1a is connected to the reproduction apparatus 2 for reproducing information recorded on the DVD 1 as shown in FIG. 1A. The following description is applicable to the case where the signal processing apparatus 1a is used in the forms shown in FIGS. 1B and 1C. For example, the logical format of the DVD 1 described later is applicable to the logical format of the broadcast signal shown in FIG. 1B or the logical format of the communication signal shown in FIG. 1C.

2. Logical Format of the DVD 1

FIG. 2 shows an example of the logical format of the DVD 1.

In the example shown in FIG. 2, the DVD 1 includes a data information recording area 10 for recording a volume and a file structure of the DVD 1, and a multi-media data area 11 for recording multi-media data including still picture data. Acoustic signal correction data 12a is stored in an area other than the data information recording area 10 and the multi-media data area 11.

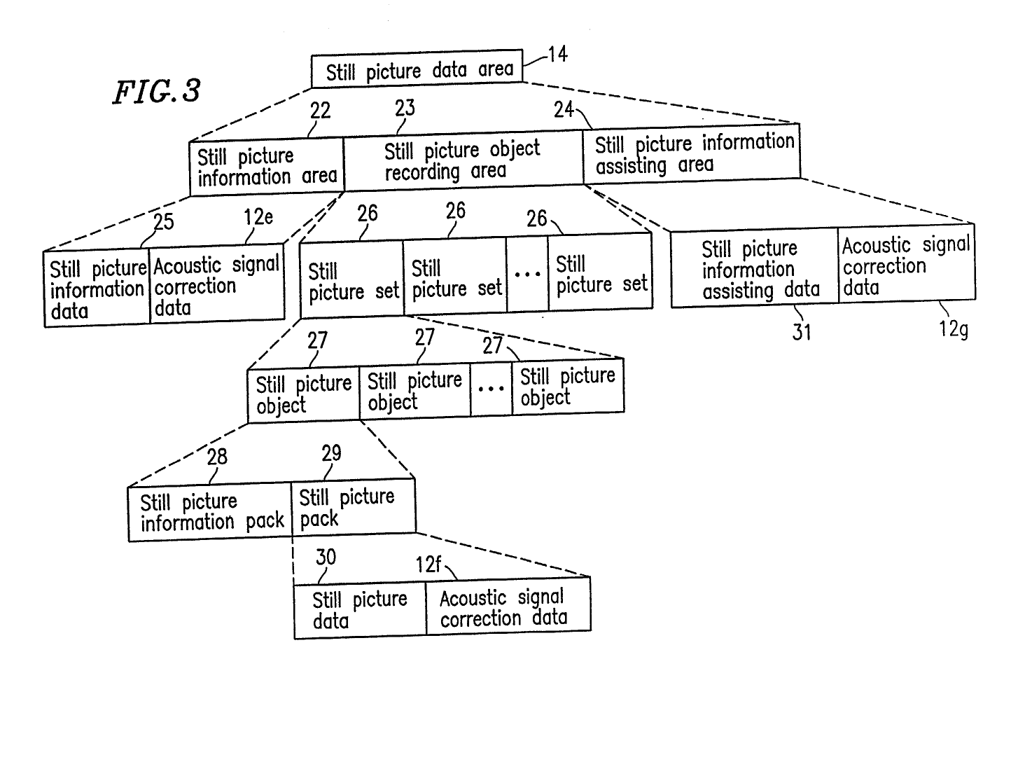

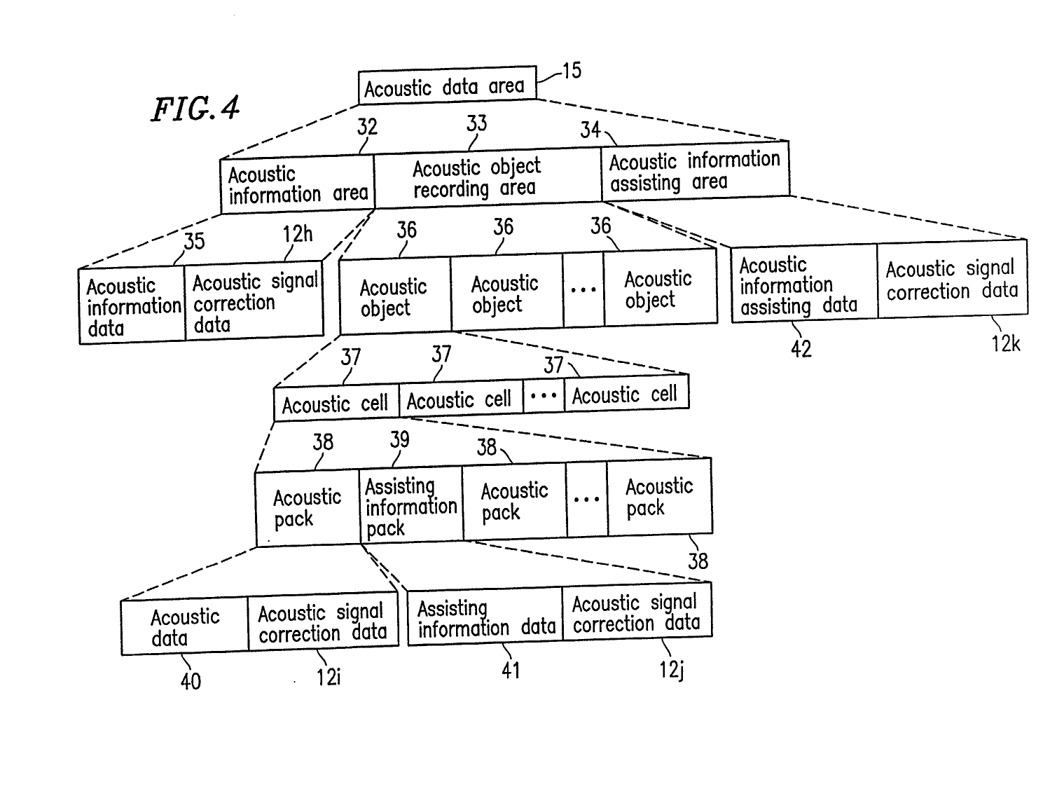

The multi-media data area 11 includes a navigation data area 13 for recording information on the entirety of the DVD 1, menu information common to the entirety of the DVD 1 or the like, a still picture data area 14 for recording data on a still picture, and an acoustic data area 15 for recording acoustic data. A detailed structure of the still picture data area 14 will be described below with reference to FIG. 3. A detailed structure of the acoustic data area 15 will be described below with reference to FIG. 4.

The navigation data area 13 includes an acoustic navigation area 16, a still picture navigation area 17, and an acoustic navigation assisting area 18.

The acoustic navigation area 16 has acoustic navigation data 19 and acoustic signal correction data 12b stored therein.

The still picture navigation area 17 has still picture navigation data 20 and acoustic signal correction data 12c stored therein.

The acoustic navigation assisting area 18 has acoustic navigation assisting data 21 and acoustic signal correction data 12d stored therein.

In this manner, the acoustic signal correction data 12b, 12c and 12d are stored in the DVD 1 so as to accompany the corresponding navigation data.

FIG. 3 shows an example of the logical format of the still picture data area 14.

The still picture data area 14 includes a still picture information area 22, a still picture object recording area 23, and a still picture information assisting area 24.

The still picture information area 22 has still picture information data 25 and acoustic signal correction data 12e stored therein.

The still picture object recording area 23 has at least one still picture set 26. Each still picture set 26 includes at least one still picture object 27. Each still picture object 27 includes a still picture information pack 28 and a still picture pack 29. The still picture pack 29 includes still picture data 30 and acoustic signal correction data 12f.

The still picture information assisting area 24 has still picture information assisting data 31 and acoustic signal correction data 12g stored therein.

In this manner, the acoustic signal correction data 12e, 12f and 12g are stored in the DVD 1 so as to accompany the corresponding data on the still picture.

FIG. 4 shows an example of the logical format of the acoustic data area 15.

The acoustic data area 15 includes an acoustic information area 32, an acoustic object recording area 33, and an acoustic information assisting area 34.

The acoustic information area 32 has acoustic information data 35 and acoustic signal correction data 12h stored therein.

The acoustic object recording area 33 has at least one acoustic object 36. Each acoustic object 36 includes at least one acoustic cell 37. Each acoustic cell 37 includes at least one acoustic pack 38 and at least one assisting information pack 39. The acoustic pack 38 includes acoustic data 40 and acoustic signal correction data 12i. The assisting information pack 39 includes assisting information data 41 and acoustic signal correction data 12j.

Each acoustic object 36 corresponds to at least one tune. Each acoustic cell 37 represents a minimum unit of the acoustic signal AS which can be reproduced and output by the reproduction apparatus 2. Each acoustic pack 38 represents one-frame acoustic signal AS obtained by dividing the acoustic signal AS into frames of a periodic predetermined time period. Each assisting information pack 39 represents a parameter or a control command used for reproducing the acoustic signal AS.

The acoustic information assisting area 34 has acoustic information assisting data 42 and acoustic signal correction data 12k stored therein.

In this manner, the acoustic signal correction data 12h, 12i, 12j and 12k are stored in the DVD 1 so as to accompany the corresponding acoustic data.

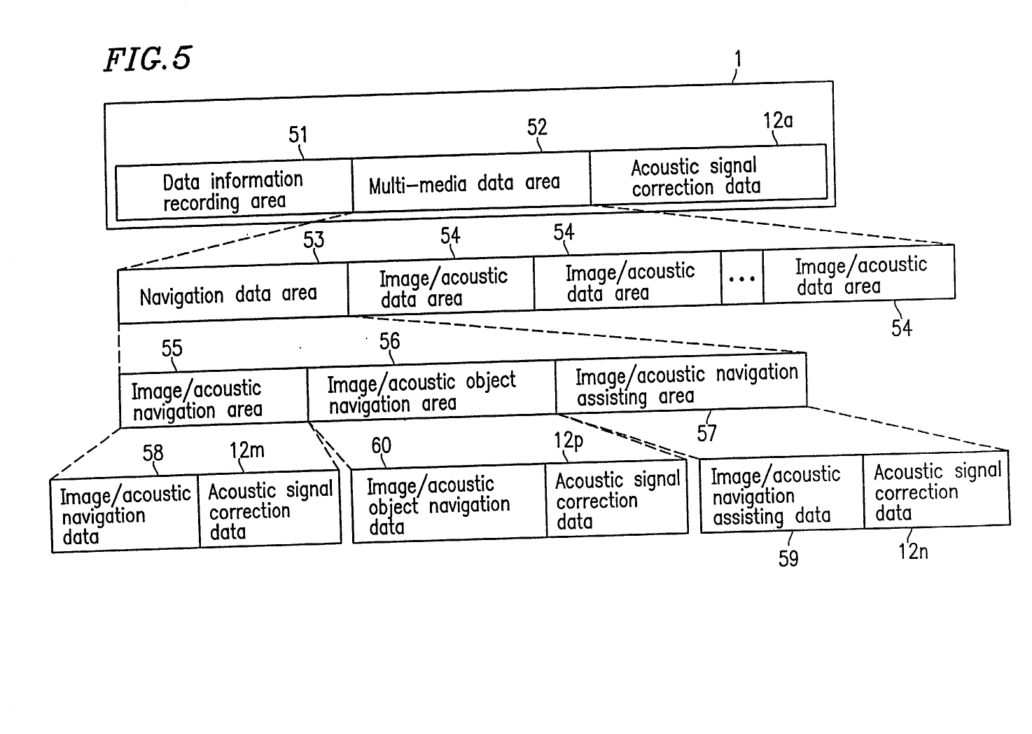

FIG. 5 shows another example of the logical format of the DVD 1.

In the example shown in FIG. 5, the DVD 1 includes a data information recording area 51 for recording a volume and a file structure of the DVD 1, and a multi-media data area 52 for recording multi-media data including moving picture data. Acoustic signal correction data 12a is stored in an area other than the data information recording area 51 and the multi-media data area 52.

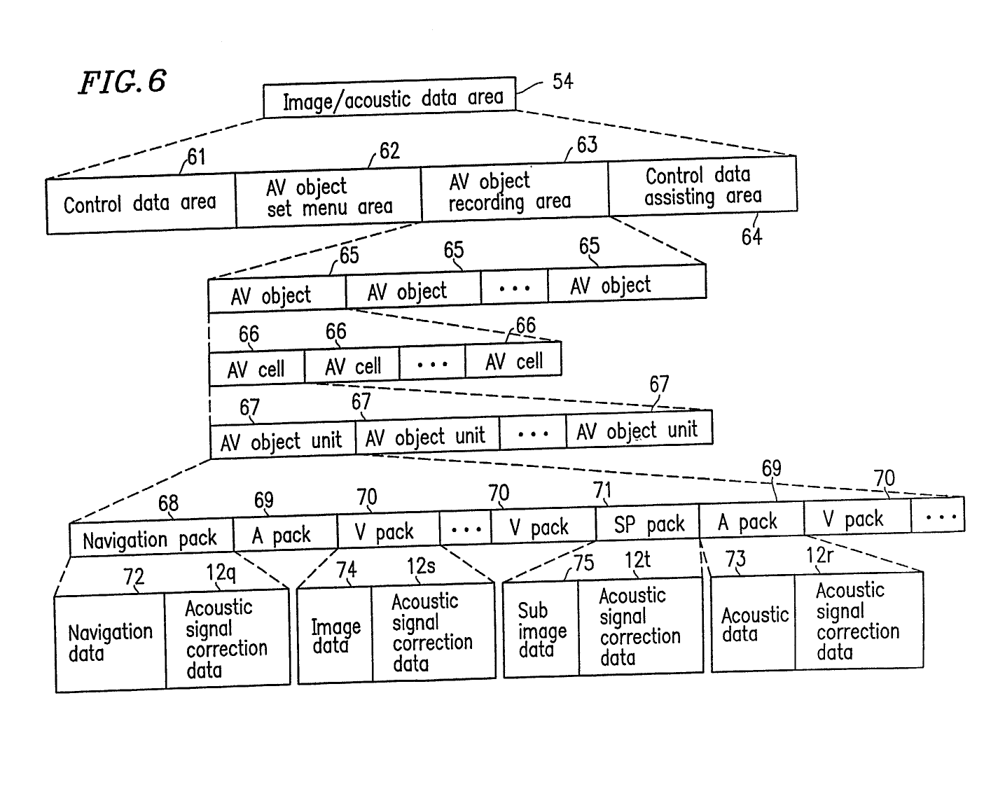

The multi-media data area 52 includes a navigation data area 53 for storing navigation data, and at least one image/acoustic data area 54 for recording image/acoustic data. A detailed structure of the image/acoustic data area 54 will be described below with reference to FIG. 6.

The navigation data represents information on the entirety of the DVD 1 and/or menu information common to the entirety of the DVD 1 (location of acoustic data area and image data area). The image signal and the video signal change in accordance with the navigation data.

The navigation data area 53 includes an image/acoustic navigation area 55, an image/acoustic object navigation area 56, and an image/acoustic navigation assisting area 57.

The image/acoustic navigation area 55 has image/acoustic navigation data 58 and acoustic signal correction data 12m stored therein.

The image/acoustic object navigation area 56 has image/acoustic object navigation data 60 and acoustic signal correction data 12p stored therein.

The image/acoustic navigation assisting area 57 has image/acoustic navigation assisting data 59 and acoustic signal correction data 12n stored therein.

In this manner, the acoustic signal correction data 12m, 12n and 12p are stored in the DVD 1 so as to accompany the corresponding navigation data.

FIG. 6 shows an example of the logical format of the image/acoustic data area 54.

The image/acoustic data area 54 includes a control data area 61 for recording control data common to the entirety of the image/acoustic data area 54, an AV object set menu area 62 for a menu common to the entirety of the image/acoustic data area 54, an AV object recording area 63, and a control data assisting area 64 for recording control assisting data common to the entirety of the image/acoustic data area 54.

The AV object recording area 63 has at least one AV object 65 stored therein. Each AV object 65 includes at least one AV cell 66. Each AV cell 66 includes at least one AV object unit 67. Each AV object unit 67 is obtained by time-division-multiplexing at least one of a navigation pack 68, an A pack 69, a V pack 70 and an SP pack 71.

The navigation pack 68 includes navigation data 72 having a pack structure and acoustic signal correction data 12q. The A pack 69 includes acoustic data 73 having a pack structure and acoustic signal correction data 12r. The V pack 70 includes image data 74 having a pack structure and acoustic signal correction data 12s. The SP pack 71 includes sub image data 75 having a pack structure and acoustic signal correction data 12t.

Each AV object 65 represents one-track image signal VS and acoustic signal AS. A track is a unit of the image signal VS and the acoustic signal AS based on which the image signal VS and the acoustic signal AS are reproduced by the reproduction apparatus 2. Each AV cell 66 represents a minimum unit of the image signal VS and the acoustic signal AS which can be reproduced and output by the reproduction apparatus 2.

In this manner, the acoustic signal correction data 12q, 12r, 12s and 12t are stored in the DVD 1 so as to accompany the corresponding image/acoustic data.

The acoustic signal correction data 12a (FIGS. 2 and 5) is stored in an area on the DVD 1 different from the area in which the image signal VS and the acoustic signal AS are stored. Accordingly, the acoustic signal correction data 12a can be output from the reproduction apparatus 2 before the image signal VS and the acoustic signal AS are output from the reproduction apparatus 2. For example, a plurality of pieces of acoustic signal correction data 12a for correcting an acoustic characteristic of a plurality of type of headphones usable by the viewer/listener 8 are stored on the DVD 1 beforehand. The acoustic signal correction data 12a which corresponds to the headphones 6 actually used by the viewer/listener 8 is selected, and the acoustic signal AS is corrected using the selected acoustic signal correction data 12a. In this manner, the acoustic signal AS can be corrected in a suitable manner for the headphones 6 actually used by the viewer/listener 8. Similarly, acoustic signal correction data 12a for realizing an acoustic characteristic desired by the viewer/listener 8 may be stored on the DVD 1 beforehand.

The acoustic signal correction data 12c (FIG. 2) and acoustic signal correction data 12e through 12g (FIG. 3) are stored in the DVD 1 so as to accompany the corresponding data on the still picture. Accordingly, the acoustic signal correction data 12c and 12e through 12g can be read from the DVD 1 when the data on the still picture is read. As a result, the acoustic signal correction data 12c and 12e through 12g can be output from the reproduction apparatus 2 in synchronization with the output of the image signal VS from the reproduction apparatus 2. Thus, the acoustic signal AS can be corrected in association with the content of the still picture displayed by the image display apparatus 7.

For example, when the image display apparatus 7 displays a site where the acoustic signal AS was recorded (for example, a concert hall or an outdoor site), the acoustic signal AS can be corrected using the acoustic signal correction data 12c and 12e through 12g which reproduce the sound field of the site where the recording was performed. As a result, the viewer/listener 8 can enjoy the acoustic characteristic matching the image.

For example, when the image display apparatus 7 displays a short range view or a distant view of a musical instrument or a singer, the acoustic signal AS can be corrected using the acoustic signal correction data 12c and 12e through 12g which reproduce the distance between the sound source to the viewer/listener 8. As a result, the viewer/listener 8 can enjoy the acoustic characteristic matching the image.

The acoustic signal AS may be recorded by the producer of the DVD 1 (content producer) on the DVD 1 so as to have an acoustic characteristic in accordance with the still picture (acoustic characteristic matching the image). Such recording is usually performed by the content producer in a mixing room or acoustic studio while adjusting the acoustic characteristic. In this case, the acoustic signal AS can be corrected using the acoustic signal correction data 12c and 12e through 12g which reproduce the sound field of the mixing room or the acoustic studio. As a result, the viewer/listener 8 can enjoy the acoustic characteristic adjusted by the content producer (acoustic characteristic matching the image).

The acoustic signal correction data 12b and 12d (FIG. 2) and the acoustic signal correction data 12h through 12k (FIG. 4) are stored on the DVD 1 so as to accompany the acoustic data. Accordingly, the acoustic signal correction data 12b, 12d and 12h through 12k can be output from the reproduction apparatus 2 in synchronization with the output of the acoustic signal AS from the reproduction apparatus 2. Thus, the acoustic signal AS can be corrected in association with the content of the acoustic signal AS.

For example, the acoustic signal AS can be corrected in accordance with the tune or the lyrics of the tune. As a result, the viewer/listener 8 can enjoy a preferable acoustic characteristic.

The acoustic signal correction data 12m, 12n, and 12p through 12t (FIGS. 5 and 6) are stored on the DVD 1 so as to accompany the data on the image including moving picture and acoustic data. Accordingly, the acoustic signal correction data 12m, 12n, and 12p through 12t can be output from the reproduction apparatus 2 in synchronization with the output of the image signal VS and the acoustic signal AS from the reproduction apparatus 2. Thus, the acoustic signal AS can be corrected in association with the content of the image (moving picture) displayed by the image display apparatus 7 and/or the content of the acoustic signal AS. As a result, the viewer/listener 8 can enjoy the acoustic characteristic matching the image.

3. Correction Command and Filter Coefficient

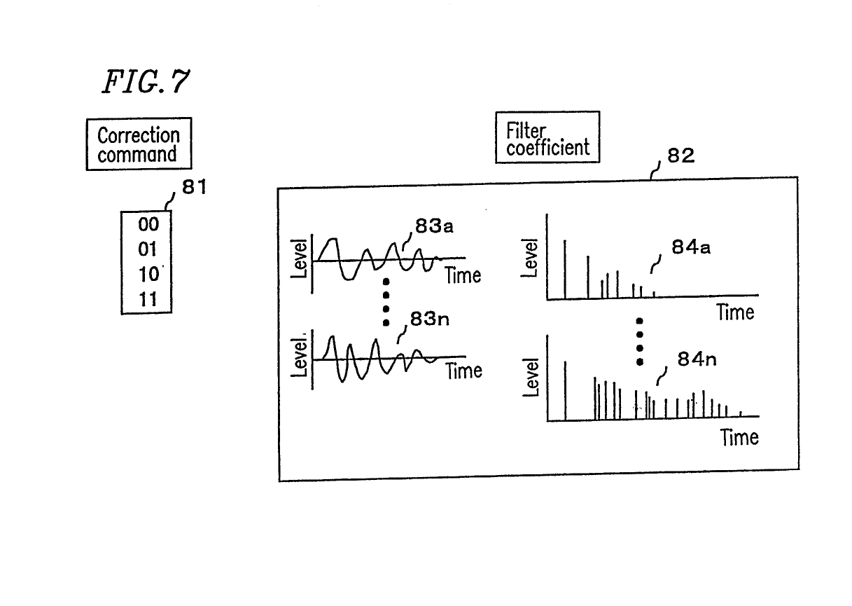

FIG. 7 shows an example of a correction command and a filter coefficient included in the acoustic signal correction data (for example, the acoustic signal correction data 12a shown in FIG. 2).

As shown in FIG. 7, a correction command 81 is represented by, for example, 2 bits. In this case, the filter coefficient stored in the memory 4 can be specified in four different ways using the correction command 81. The correction command 81 can specify one filter coefficient or a plurality of filter coefficients.

A filter coefficient 82 is, for example, any one of filter coefficients 83a through 83n or any one of filter coefficients 84a through 84n.

The filter coefficients 83a through 83n each indicate an “impulse response” representing an acoustic transfer characteristic from the sound source of a predetermined sound field to a listening point (a transfer function showing an acoustic characteristic of a direct sound). The filter coefficients 84a through 84n each indicate a “reflection structure” representing a level of the sound emitted from the sound source with respect to the time period required for the sound to reach the listening point in a predetermined sound field (an acoustic characteristic of a reflection).

Each of the plurality of filter coefficients stored in the memory 4 is any one of the filter coefficients 83a through 83n or any one of the filter coefficients 84a through 84n. It is preferable that a plurality of filter coefficient of different types are stored, so that acoustic characteristics of various fields can be provided to the viewer/listener 8.

For example, using the filter coefficient 83a as the filter coefficient 82, a convolution calculation of the impulse response corresponding to the filter coefficient 83a can be performed by the correction section 5. As a result, the viewer/listener 8 can listen to a sound reproducing an acoustic characteristic from the sound source to the listening point of a predetermined sound field. Using the filter coefficient 84a as the filter coefficient 82, the viewer/listener 8 can listen to a sound reproducing a reflection structure of a predetermined sound field.

In the case where the correction command 81 is represented by 2 bits, the capacity required to record the correction command 81 can be sufficiently small. Accordingly, the capacity of the DVD 1 is not excessively reduced even when the correction command 81 is recorded on the DVD 1.

It is preferable that the correction command 81 is stored in at least one of the navigation data area 13 (FIG. 2), the still picture data area 14 (FIG. 2) and the acoustic data area 15 (FIG. 2) and therefore, the filter coefficient 82 is stored in an area other than the navigation data area 13, the still picture data area 14 and the acoustic data area 15 (for example, the assisting data area). In this case, reproduction of the image signal VS, the acoustic signal AS or the navigation data is prevented from being interrupted by reproduction of the filter coefficient 82 which requires a larger capacity than the correction command 81.

As described above, the signal processing apparatus 1a according to the present invention allows the viewer/listener 8 to listen to the sound which is matched to the image displayed by the image display apparatus 7 through the headphones 6. The correction performed on the acoustic signal AS by the correction section 5 changes in accordance with a change in the image signal VS and/or a change in the acoustic signal AS. As a result, the viewer/listener 8 does not notice any discrepancies in a relationship between the image and the sound.

The filter coefficients in the memory 4 used for correcting the acoustic signal AS can be appropriately added, selected or altered. Accordingly, the acoustic characteristic can be corrected in accordance with the headphones 6 actually used by the viewer/listener 8 or in accordance with individual body features of the viewer/listener 8 (for example, the features of the ears and face of the viewer/listener 8), in addition to the acoustic signal AS being corrected in accordance with the change in the image signal VS and/or the change in the acoustic signal AS.

The capacity required to record the correction command 81 which is used to select the filter coefficient in the memory 4 can be relatively small. Accordingly, the capacity of the DVD 1 is not excessively reduced even when the correction command 81 is recorded on the DVD 1. The time period required to read the correction command 81 from the DVD 1 can be relatively short. Accordingly, the filter coefficient can be frequently switched in accordance with a change in the image signal VS or a change in the acoustic signal AS. As a result, the manner of correcting the acoustic signal AS can be changed so as to better reflect the intent of the producer of the image signal VS and the acoustic signal AS (contents).

In the case where a broadcast signal or a communication signal is received and acoustic signal correction data included in the broadcast signal or the communication signal is input to the signal processing apparatus 1a, the correction command 81 is input to the signal processing apparatus 1a by receiving the broadcast signal or the communication signal. A band width required to broadcast or communicate the correction command 81 can be relatively small. Therefore, the band width for the broadcast signal or the communication signal is not excessively reduced even when the correction command 81 is broadcast or communicated.

By correcting the acoustic signal AS based on the acoustic signal correction data recorded on the DVD 1 as described above, the viewer/listener 8 can obtain a favorable viewing and listening environment.

In this example, still picture data and acoustic data are recorded on the DVD 1. Even when only the acoustic data is recorded on the DVD 1, the acoustic signal AS can be corrected in a similar manner. In this case, an effect similar to that described above is provided.

In this example, a filter coefficient included in the acoustic signal correction data recorded on the DVD 1 is stored in the memory 4. The filter coefficient may be stored in the memory 4 beforehand. Alternatively, a filter coefficient stored in a flexible disk or a semiconductor memory can be transferred to the memory 4. Still alternatively, the filter coefficient may be input to the memory 4 from the DVD 1 when necessary. In these cases also, an effect similar to that described above is provided.

In this example, the correction command is represented by 2 bits. The present invention is not limited to this. The bit length of correction commands may be increased or decreased in accordance with the type of the filter coefficient stored in the memory 4 and the capacity of the DVD 1. The correction command may be of any content so long as the correction command can specify the filter coefficient used for correcting the acoustic signal AS. In this case also, an effect similar to that described above is provided.

In this example, a filter coefficient representing an impulse response and a filter coefficient representing a reflection structure are described as filter coefficients. Any other type of filter coefficient which has a structure for changing the acoustic characteristic is usable. In this case also, an effect similar to that described above is provided. A filter coefficient representing an impulse response and a filter coefficient representing a reflection structure can be used together.

In this example, the corrected acoustic signal AS is output to the headphones 6. The device to which corrected acoustic signal AS is output is not limited to the headphones 6. The corrected acoustic signal AS may be output to any type of transducer (for example, a speaker) which has a function of converting the electric acoustic signal AS into a sound wave. In this case also, an effect similar to that described above is provided.

4. Use of a Buffer Memory 87

In order to correct the acoustic signal AS without interrupting the output from the reproduction apparatus 2, the signal processing apparatus 1a (FIG. 1A) preferably includes a buffer memory 87. Hereinafter, use of the buffer memory 87 will be described.

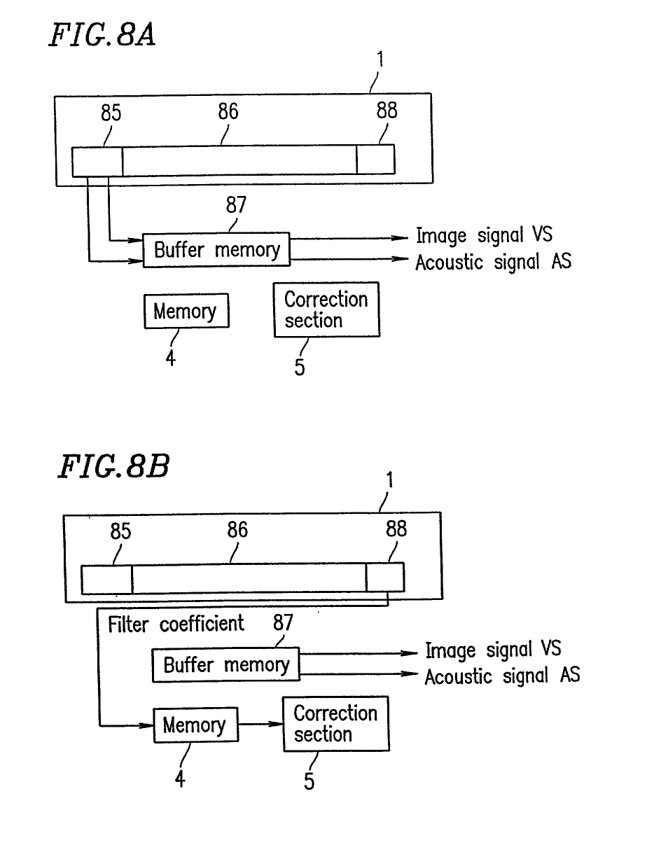

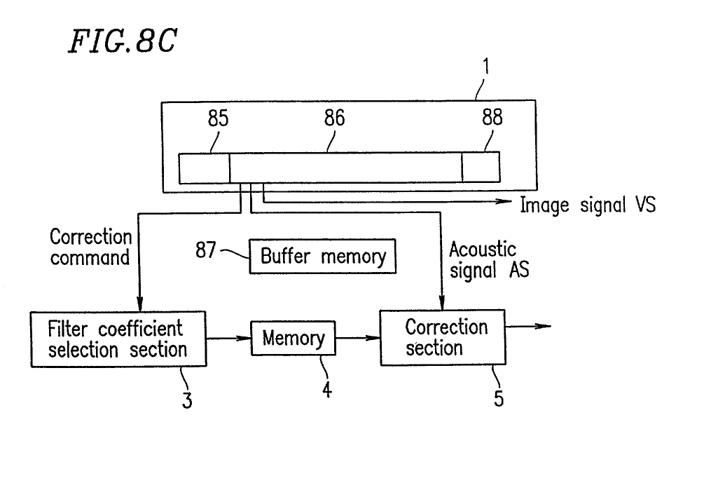

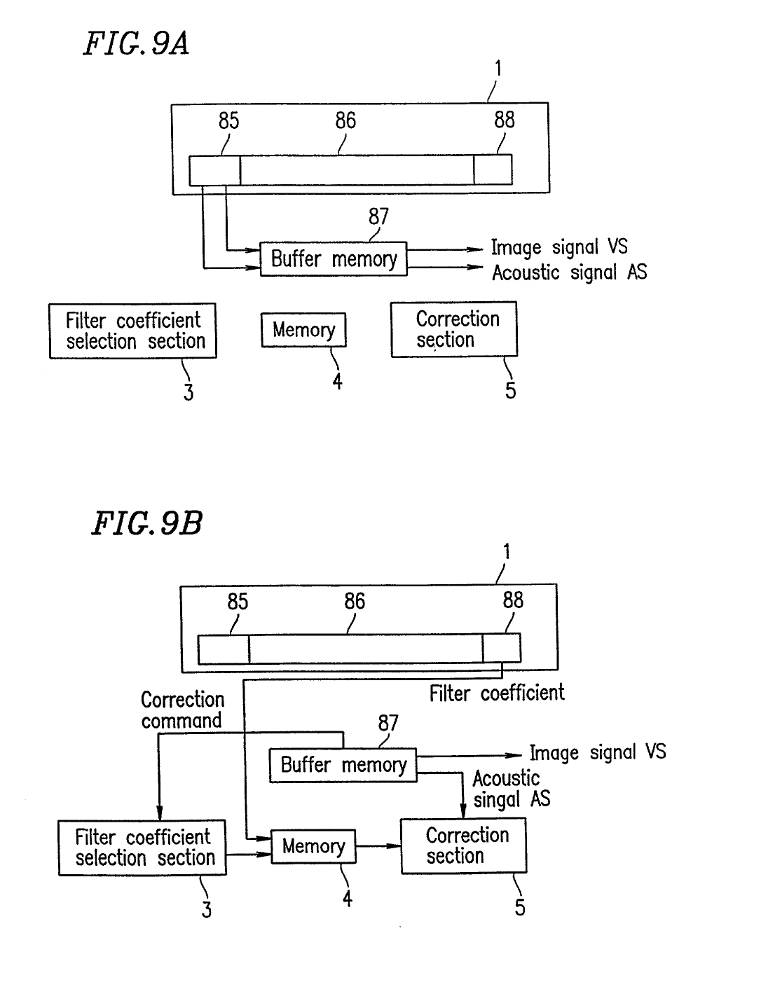

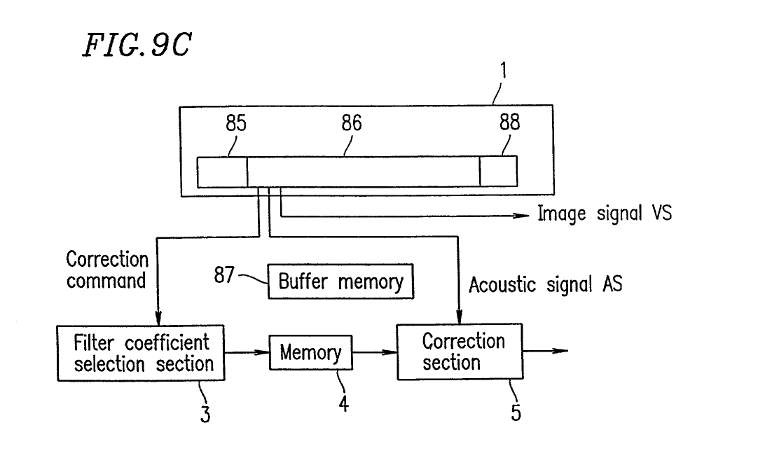

FIGS. 8A through 8C and 9A through 9C each show a state where the image signal VS, the acoustic signal AS and acoustic signal correction data recorded on the DVD 1 are reproduced by the reproduction apparatus 2.

FIGS. 8A and 9A each show an initial state immediately after the reproduction of the data on the DVD 1 is started. FIGS. 8B and 9B each show a state later than the state shown in FIGS. 8A and 9A. FIGS. 8C and 9C each show a state later than the state shown in FIGS. 8B and 9B.

In FIGS. 8A through 8C, reference numeral 85 represents an initial data area which is first reproduced after the reproduction of the data on the DVD 1 is started. Reference numeral 86 represents a data area immediately subsequent to the initial data area 85. Reference numeral 88 represents an area in which acoustic signal correction data 12 is recorded.

Reference numeral 87 represents a buffer memory for temporarily accumulating data reproduced from the initial data area 85 and sequentially outputting the accumulated data. The buffer memory 87 is controlled so that the speed for inputting data to the buffer memory 87 is higher than the speed for outputting the data from the buffer memory 87. For example, the speed for outputting the data from the buffer memory 87 is a speed required to perform a usual reproduction (reproduction at the 1× speed) of the image signal VS or the acoustic signal AS from the DVD 1. The speed for inputting the data to the buffer memory 87 is hither than the speed required to perform the usual reproduction (reproduction at the 1× speed) of the image signal VS or the acoustic signal AS from the DVD 1.

At least one filter coefficient included in the acoustic signal correction data recorded on the DVD 1 is stored in the memory 4 during the output of the image signal VS or the acoustic signal AS from the buffer memory 87.

The time period required for outputting the image signal VS or the acoustic signal AS from the buffer memory 87 is equal to or longer than the time period required for storing the at least one filter coefficient included in the acoustic signal correction data in the memory 4.

In the initial state shown in FIG. 8A, the data recorded in the initial data area 85 is reproduced at a higher speed than the speed required for the usual reproduction. As a result, the image signal VS and the acoustic signal AS are input to the buffer memory 87 at a higher speed than the speed required for the usual reproduction. The buffer memory 87 accumulates the output from the initial data area 85, and also outputs the image signal VS and the acoustic signal AS accumulated in the buffer memory 87 at the speed required for the usual reproduction.

Upon termination of the output of the data 12 from the initial data area 85, the initial state shown in FIG. 8A is transferred to the state shown in FIG. 8B.

In the state shown in FIG. 8B, the acoustic signal correction data 12 recorded in the area 88 is reproduced at a higher speed than the speed required for the usual reproduction. As a result, a filter coefficient included in the acoustic signal correction data 12 is output to the memory 4. The buffer memory 87 outputs the image signal VS and the acoustic signal AS accumulated in the buffer memory 87 at the speed required for the usual reproduction.

Upon termination of the output of the data from the area 88, the state shown in FIG. 8B is transferred to the state shown in FIG. 8C.

In the state shown in FIG. 8C, the data recorded in the data area 86 immediately subsequent to the initial data area 85 is reproduced at the speed required for the usual reproduction. As a result, a correction command recorded in the data area 86 is output to the filter coefficient selection section 3. In accordance with the correction command, the filter coefficient selection section 3 outputs, to the memory 4, a signal specifying a filter coefficient to be selected among the plurality of filter coefficients stored in the memory 4. The memory 4 outputs the filter coefficient specified by the filter coefficient selection section 3 to the correction section 5. The correction section 5 corrects the acoustic signal AS using the filter coefficient output from the memory 4.

In the initial state shown in FIG. 9A, the data recorded in the initial data area 85 is reproduced at a higher speed than the speed required for the usual reproduction. As a result, the image signal VS and the acoustic signal AS are input to the buffer memory 87 at a higher speed than the speed required for the usual reproduction. The buffer memory 87 accumulates the output from the initial data area 85, and also outputs the image signal VS and the acoustic signal AS accumulated in the buffer memory 87 at the speed required for the usual reproduction.

The correction command recorded in the initial data area 85 is output to the filter coefficient selection section 3 via the buffer memory 87. In accordance with the correction command, the filter coefficient selection section 3 outputs, to the memory 4, a signal specifying a filter coefficient to be selected among the plurality of filter coefficients stored in the memory 4. The memory 4 outputs the filter coefficient specified by the filter coefficient selection section 3 to the correction section 5. The correction section 5 corrects the acoustic signal AS using the filter coefficient output from the memory 4. (FIG. 9A does not show the processing performed after the correction command is output to the filter coefficient selection section 3 until the acoustic signal AS is corrected.) Since no filter coefficient is reproduced from the initial data area 85, the acoustic signal AS recorded in the initial data area 85 is output without being corrected (or corrected using one of the plurality of filter coefficients stored in the memory 4 beforehand).

Upon termination of the output of the data from the initial data area 85, the initial state shown in FIG. 9A is transferred to the state shown in FIG. 9B.

In the state shown in FIG. 9B, the acoustic signal correction data 12 recorded in the area 88 is reproduced at a higher speed than the speed required for the usual reproduction. As a result, a filter coefficient included in the acoustic signal correction data 12 is output to the memory 4. The buffer memory 87 outputs the image signal VS and the acoustic signal AS accumulated in the buffer memory 87 at the speed required for the usual reproduction and outputs the correction command to the filter coefficient selection section 3.

Upon termination of the output of the acoustic signal correction data 12 from the area 88, the state shown in FIG. 9B is transferred to the state shown in FIG. 9C.

In the state shown in FIG. 9C, the data recorded in the data area 86 immediately subsequent to the initial data area 85 is reproduced at the speed required for the usual reproduction. As a result, a correction command recorded in the data area 86 is output to the filter coefficient selection section 3. In accordance with the correction command, the filter coefficient selection section 3 outputs, to the memory 4, a signal specifying a filter coefficient to be selected among the plurality of filter coefficients stored in the memory 4. The memory 4 outputs the filter coefficient specified by the filter coefficient selection section 3 to the correction section 5. The correction section 5 corrects the acoustic signal AS using the filter coefficient output from the memory 4.

By effectively using the buffer memory 87 as described above, the acoustic signal AS can be corrected based on the acoustic signal correction data 12 without interrupting the output of any of the image signal VS or the acoustic signal AS from the reproduction apparatus 2.

In this example, the acoustic signal AS recorded in the initial data area 85 is output without being corrected (or corrected using one of the plurality of filter coefficients stored in the memory 4 beforehand). The initial data area 85 preferably stores an acoustic signal AS which does not need to be corrected. In the initial data area 85, an acoustic signal AS and an image signal VS on a title of the content (for example, a movie) of the DVD 1 and/or an advertisement or the like provided by the content producer, for example, may be stored.

In this example, after reproduction of the data on the DVD 1 is started, the data stored in the initial data area 85 is first reproduced. Alternatively, after reproduction of the data on the DVD 1 is started, the data stored in the area 88 having the acoustic signal correction data 12 recorded therein may be first reproduced. In this case also, the acoustic signal AS can be corrected based on the acoustic signal correction data 12 without interrupting the output of any of the image signal VS or the acoustic signal AS from the reproduction apparatus 2.

In this example, image data and acoustic data are recorded in the initial data area 85. Alternatively, either one of the image data or the acoustic data, or other data (for example, navigation data) may be recorded in the initial data area 85. In this case also, an effect similar to that described above is provided.

5. Structure of the Correction Section 5

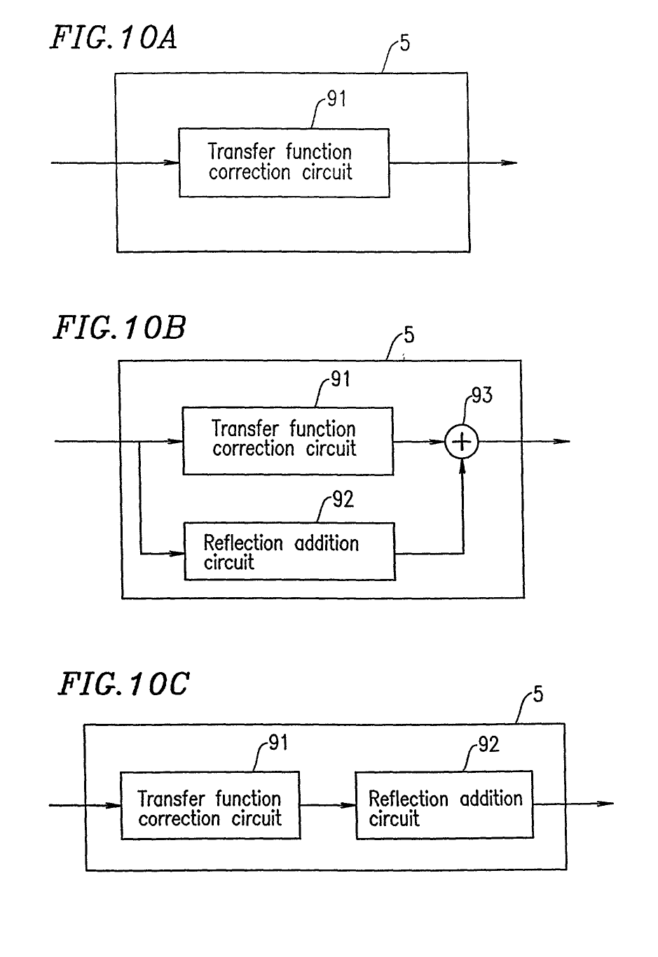

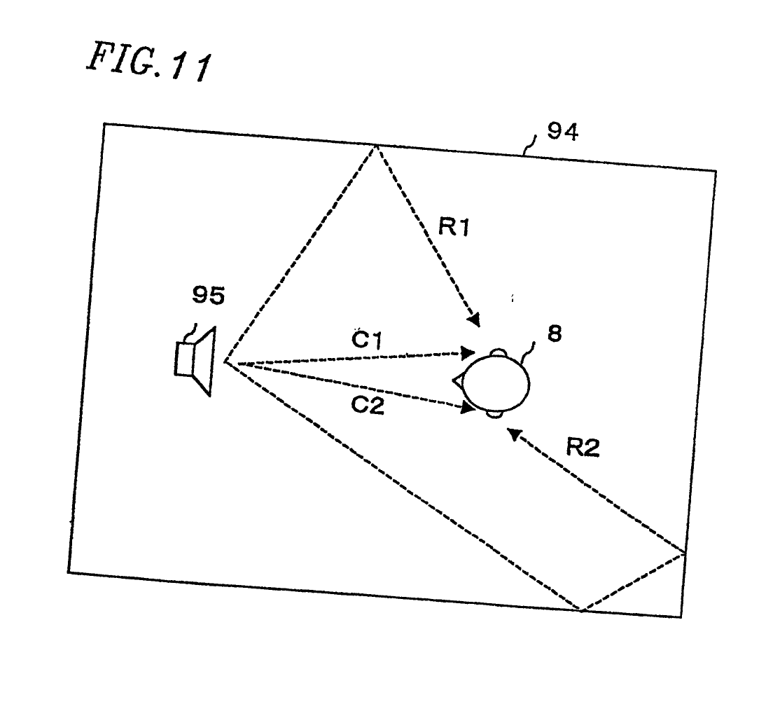

FIG. 10A shows an exemplary structure of the correction section 5 (FIG. 1A). The correction section 5 shown in FIG. 10A includes a transfer function correction circuit 91 for correcting a transfer function of an acoustic signal AS in accordance with at least one filter coefficient which is output from the memory 4.

In the following description, a sound wave in the space is transferred as shown in FIG. 11.

In FIG. 11, reference numeral 94 represents a space forming a sound field, and reference numeral 95 represents a sound source positioned at a predetermined position. C1 represents a transfer characteristic of a direct sound from a virtual sound source 95 to the right ear of the viewer/listener 8, C2 represents a transfer characteristic of a direct sound from the virtual sound source 95 to the left ear of the viewer/listener 8, R1 represents a transfer characteristic of a reflection from the virtual sound source 95 to the right ear of the viewer/listener 8, and R2 represents a transfer characteristic of a reflection from the virtual sound source 95 to the left ear of the viewer/listener 8.

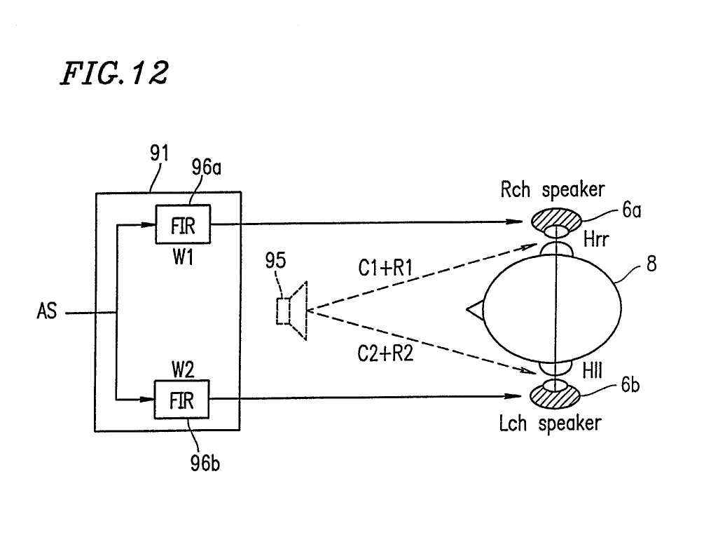

Hereinafter, with reference to FIG. 12, how to determine a filter coefficient of the transfer function correction circuit 91 is determined when the viewer/listener 8 receives the sound through the headphones 6.

FIG. 12 shows an exemplary structure of the transfer function correction circuit 91.

The transfer function correction circuit 91 includes an FIR filter 96a and an FIR filter 96b. The acoustic signal AS is input to the FIR filters 96a and 96b. An output from the FIR filter 96a is input to a right channel speaker 6a of the headphones 6. An output from the FIR filter 96b is input to a left channel speaker 6b of the headphones 6.

The case of reproducing the sound from the virtual sound source 95 by the headphones 6 will be described. A transfer function of the FIR filter 96a is W1, a transfer function of the FIR filter 96b is W2, a transfer function from the right channel speaker 6a of the headphones 6 to the right ear of the viewer/listener 8 is Hrr, and a transfer function from the left channel speaker 6b of the headphones 6 to the left ear of the viewer/listener 8 is Hll. In this case, expression (1) is formed.

(C1+R1)=W1·Hrr

(C2+R2)=W2·Hll ...expression (1)

By using W1 and W2 obtained by expression (1) respectively as the transfer functions of the FIR filters 96a and 96b, the sound from the virtual sound source 95 can be reproduced by the headphones 6. In other words, while the sound is actually emitted from the headphones 6, the viewer/listener 8 can perceive the sound as if it was emitted from the virtual sound source 95.

Based on expression (1), the transfer function W1 of the FIR filter 96a and the transfer function W2 of the FIR filter 96b are given by expression (2).

W1=(C1+R1)/Hrr

W2=(C2+R2)/Hll ...expression (2)

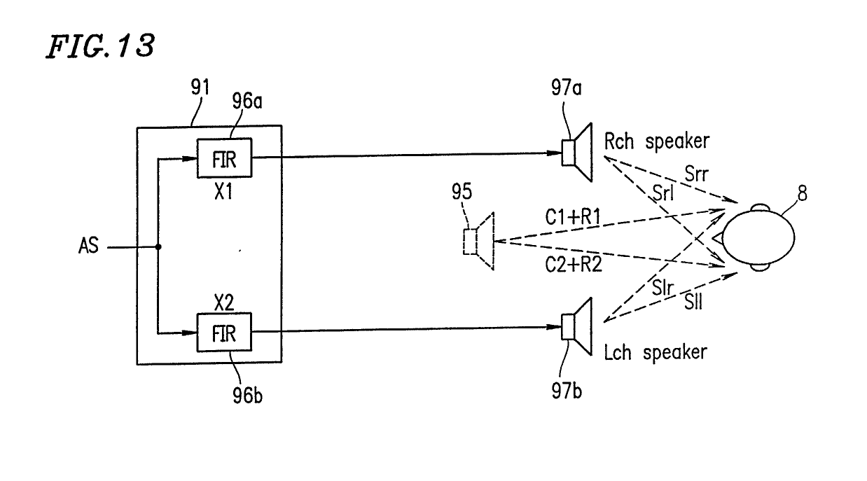

Hereinafter, with reference to FIG. 13, how to determine a filter coefficient of the transfer function correction circuit 91 is determined when the viewer/listener 8 receives the sound through a speaker 97a and a speaker 97b.

FIG. 13 shows an exemplary structure of the transfer function correction circuit 91.

The transfer function correction circuit 91 includes an FIR filter 96a and an FIR filter 96b. The acoustic signal AS is input to the FIR filters 96a and 96b. An output from the FIR filter 96a is input to a right channel speaker 97a and converted into a sound wave by the speaker 97a. An output from the FIR filter 96b is input to a left channel speaker 97b and converted into a sound wave by the speaker 97b.

The case of reproducing the sound from the virtual sound source 95 by the speakers 97a and 97b will be described. A transfer function of the FIR filter 96a is X1, and a transfer function of the FIR filter 96b is X2. A transfer function from the speaker 97a to the right ear of the viewer/listener 8 is Srr, and a transfer function from the speaker 97a to the left ear of the viewer/listener 8 is Srl. A transfer function from the speaker 97b to the right ear of the viewer/listener 8 is Slr, and a transfer function from the speaker 97b to the left ear of the viewer/listener 8 is Sll. In this case, expression (3) is formed.

(C1+R1)=X1·Srr+X2·Slr

(C2+R2)=X1·Srl+X2·Sll ...expression (3)

By using X1 and X2 obtained by expression (3) respectively as the transfer functions of the FIR filters 96a and 96b, the sound from the virtual sound source 95 can be reproduced by the speakers 97a and 97b. In other words, while the sound is actually emitted from the speakers 97a and 97b, the viewer/listener 8 can perceive the sound as if it was emitted from the virtual sound source 95.

Based on expression (3), the transfer function X1 of the FIR filter 96a and the transfer function X2 of the FIR filter 96b are given by expression (4).

X1={Sll·(C1+R1)−Slr·(C2+R2)}/(Srr·Sll−Srl·Slr)

X2={Srr·(C2+R2)−Srl·(C1+R1)}/(Srr·Sll−Srl·Slr) ... expression (4)

FIG. 10B shows another exemplary structure of the correction section 5 (FIG. 1A).

The correction section 5 shown in FIG. 10B includes a transfer function correction circuit 91 for correcting a transfer function of an acoustic signal AS in accordance with at least one filter coefficient which is output from the memory 4, a reflection addition circuit 92 for adding a reflection to the acoustic signal AS in accordance with at least one filter coefficient which is output from the memory 4, and an adder 93 for adding the output from the transfer function correction circuit 91 and the output from the reflection addition circuit 92.

The transfer function correction circuit 91 has a filter coefficient for reproducing a transfer characteristic of a direct sound from the virtual sound source 95 to the viewer/listener 8. The operation of the transfer function correction circuit 91 shown in FIG. 10B is the same as that of the transfer function correction circuit 91 shown in FIG. 10A except that (C1+R1) and (C2+R2) in expressions (1) through (4) are respectively replaced with C1 and C2. Therefore, the operation of the transfer function correction circuit 91 will not be described in detail.

The reflection addition circuit 92 has a filter coefficient for defining the level of the sound emitted from the virtual sound source 95 and reflected at least once with respect to the time period required for the sound to reach the viewer/listener 8.

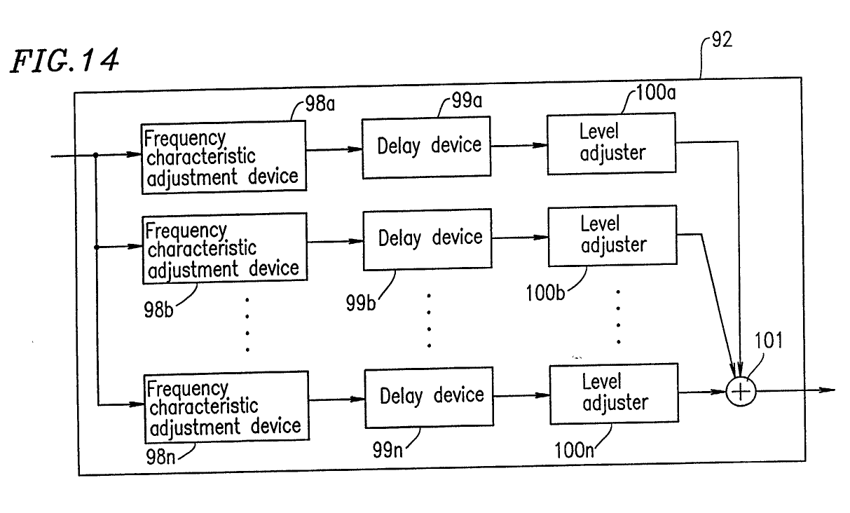

FIG. 14 shows an exemplary structure of the reflection addition circuit 92.

As shown in FIG. 14, the reflection addition circuit 92 includes frequency characteristic adjustment devices 98a through 98n for adjusting the frequency characteristic of the acoustic signal AS, delay devices 99a through 99n for delaying the outputs from the respective frequency characteristic adjustment devices 98a through 98n by predetermined time periods, level adjusters 100a through 100n for performing gain adjustment of the outputs from the respective delay devices 99a through 99n, and an adder 101 for adding the outputs from the level adjusters 100a through 100n. The output from the adder 101 is an output from the reflection addition circuit 92.

The frequency characteristic adjustment devices 98a through 98n adjust the frequency characteristic of the acoustic signal AS by varying the level of a certain frequency band component or performing low pass filtering or high pass filtering.

In this manner, the reflection addition circuit 92 generates n number of independent reflections from the acoustic signal AS. The transfer functions R1 and R2 of the reflection in a space 94 can be simulated by adjusting the frequency characteristic adjustment devices 98a through 98n, the delay devices 99a through 99n, and the level adjusters 100a through loon. This means that a signal other than a direct sound can be realized by the reflection addition circuit 92.

The transfer function correction circuit 91 shown in FIG. 10B can have a smaller number of taps of the FIR filters 96a and 96b than those of FIG. 10A. The reason for this is because the FIR filters 96a and 96b in FIG. 10B need to only represent the transfer characteristic of the direct sound among the sounds reaching from the virtual sound source 95 to the viewer/listener 8, unlike the case of FIG. 10A.

The calculation time of the reflection addition circuit 92 can be usually shorter than the calculation time period of the FIR filters, which have a large number of taps. Hence, the structure in FIG. 10B can reduce the calculation time as compared to the structure in FIG. 10A.

The frequency characteristic adjustment devices 98a through 98n, the delay devices 99a through 99n and the level adjusters 100a through 100n need not be connected in the order shown in FIG. 14. A similar effect is provided even when they are connected in a different order.

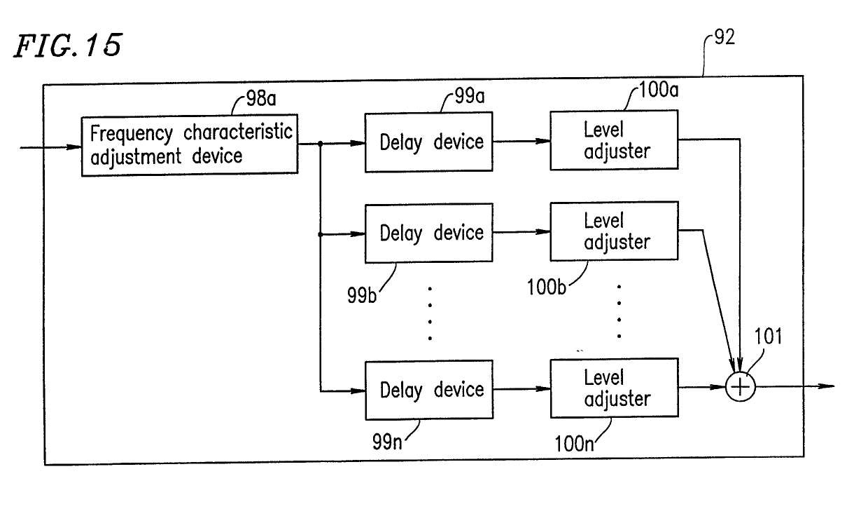

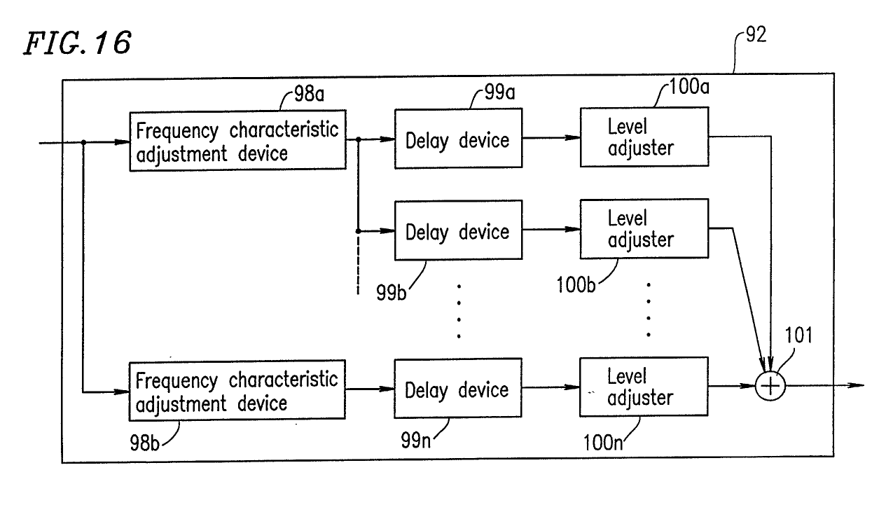

The number of the frequency characteristic adjustment devices need not match the number of the reflections. For example, as shown in FIG. 15, the reflection addition circuit 92 may include only one frequency characteristic adjustment device 98a. In this case, the frequency characteristic adjustment device 98a may correct a characteristic of the representative reflection (for example, a frequency characteristic required to generate a reflection having the largest gain). Alternatively, as shown in FIG. 16, by setting an average characteristic of a plurality of similar reflections, the number of the frequency characteristic adjustment devices can be reduced.

Although not shown, a reflection can be generated only by the delay devices 99a through 99n and the level adjusters 100a through 100n without using the frequency characteristic adjustment devices 98a through 98n. In this case, the precision of simulating the space 94 is lowered but still an effect similar to the above-described effect is provided.

In FIGS. 15 and 16, the delay devices 99a through 99n and the level adjusters 100a through 100n may be connected in an opposite order to the order shown. An effect similar to that described above is provided.

FIG. 10C shows still another exemplary structure of the correction section 5 (FIG. 1A).

The correction section 5 shown in FIG. 10C includes a transfer function correction circuit 91 for correcting a transfer function of an acoustic signal AS in accordance with at least one filter coefficient which is output from the memory 4, and a reflection addition circuit 92 connected to an output of the transfer function correction circuit 91 for adding a reflection to the output from the transfer function correction circuit 91 in accordance with at least one filter coefficient which is output from the memory 4.

The transfer function correction circuit 91 has a filter coefficient for reproducing a transfer characteristic of a direct sound from the virtual sound source 95 to the viewer/listener 8. The operation of the transfer function correction circuit 91 shown in FIG. 10C is the same as that of the transfer function correction circuit 91 shown in FIG. 10A except that (C1+R1) and (C2+R2) in expressions (1) through (4) are respectively replaced with C1 and C2. Therefore, the operation of the transfer function correction circuit 91 will not be described in detail.

The reflection addition circuit 92 has a filter coefficient for defining the level of the sound emitted from the virtual sound source 95 and reflected at least once with respect to the time period required for the sound to reach the viewer/listener 8.

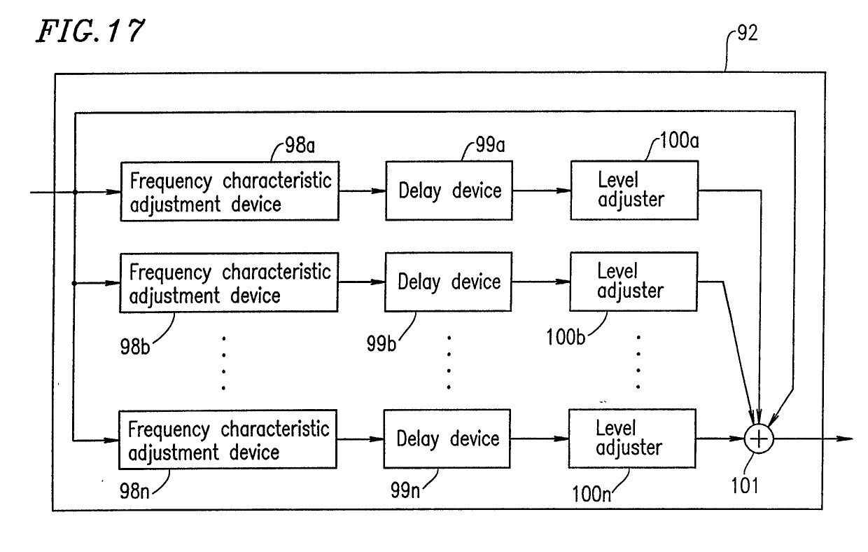

FIG. 17 shows an exemplary structure of the reflection addition circuit 92.

The structure shown in FIG. 17 is the same as that of FIG. 14 except that the acoustic signal AS input to the reflection addition circuit 92 is input to the adder 101. Identical elements previously discussed with respect to FIG. 14 bear identical reference numerals and the detailed descriptions thereof will be omitted.

The acoustic signal As is input to the frequency characteristic adjustment devices 98a through 98n and also input to the adder 101. By using the output from the adder 101 as the output from the correction section 5, the sound from the virtual sound source 95 can be reproduced by the headphones 6 or the speakers 97a and 97b in a manner similar to that shown in FIGS. 10A and 10B.

An input signal to the frequency characteristic adjustment devices 98a through 98n is an output signal from the transfer function correction circuit 91. Therefore, a reflection generated in consideration of the transfer characteristic of the direct sound from the virtual sound source 95 to the viewer/listener 8 is added. This is preferable for causing the viewer/listener 8 to perceive as if the sound they heard was emitted from the virtual sound source 95.

The frequency characteristic adjustment devices 98a through 98n, the delay devices 99a through 99n and the level adjusters 100a through 100n need not be connected in the order shown in FIG. 17. A similar effect is provided even when they are connected in a different order.

The number of the frequency characteristic adjustment devices need not match the number of the reflections. For example, as shown in FIG. 15, the reflection addition circuit 92 may include only one frequency characteristic adjustment device 98a. In this case, the frequency characteristic adjustment device 98a may correct a characteristic of the representative reflection (for example, a frequency characteristic required to generate a reflection having the largest gain). Alternatively, as shown in FIG. 16, by setting an average characteristic of a plurality of similar reflections, the number of the frequency characteristic adjustment devices can be reduced.

Although not shown, a reflection can be generated only by the delay devices 99a through 99n and the level adjusters 100a through 100n without using the frequency characteristic adjustment devices 98a through 98n. In this case, the precision of simulating the space 94 is lowered but still an effect similar to the above-described effect is provided.

In FIGS. 15 and 16, the delay devices 99a through 99n and the level adjusters 100a through 100n may be connected in an opposite order to the order shown. An effect similar to that described above is provided.

In this example, there are two reflections R1 and R2. Even when there are more reflections, an effect similar to that described above is provided.

In this example, there is only one virtual sound source 95. In the case where a plurality of virtual sound sources 95 are provided, the above-described processing is performed for each virtual sound source. Thus, while the sound is actually emitted from the headphones 6 or from the speakers 97a and 97b, the viewer/listener 8 can perceive the sound as if it was emitted from the plurality of virtual sound sources 95.

6. Structure of the Filter Coefficient Selection Section 3

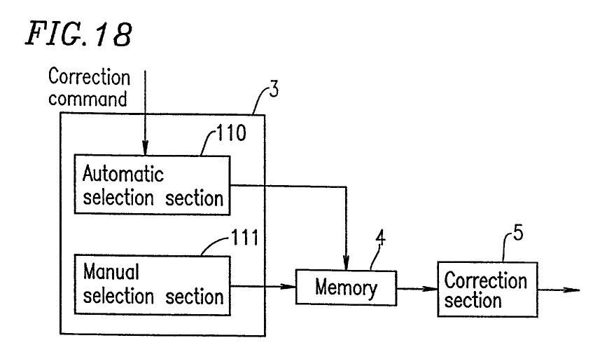

FIG. 18 shows an exemplary structure of the filter coefficient selection section 3 (FIG. 1A).

As shown in FIG. 18, the filter coefficient selection section 3 includes an automatic selection section 110 f or automatically selecting at least one of the plurality of filter coefficients stored in the memory 4, in accordance with a correction command, and a manual selection section 111 for manually selecting at least one of the plurality of filter coefficients stored in the memory 4.

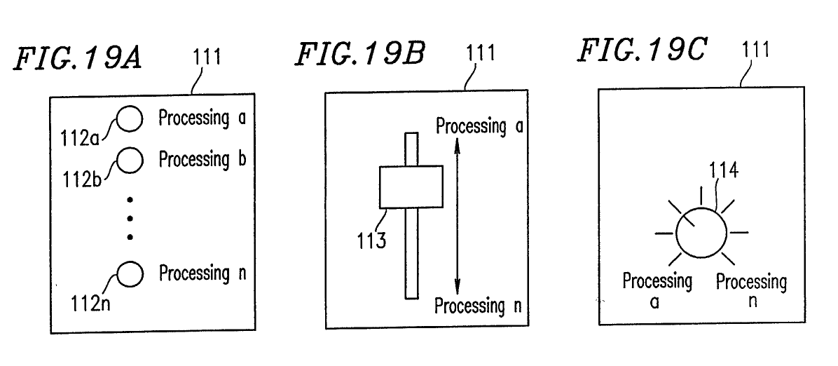

The manual selection section 111 may include, for example, a plurality of push-button switches 112a through 112n as shown in FIG. 19A, a slidable switch 113 as shown in FIG. 19B, or a rotary switch 114 as shown in FIG. 19C. By selecting a desired type of signal processing, the viewer/listener 8 can select at least one of the plurality of filter coefficients stored in the memory 4. The selected filter coefficient is output to the correction section 5.

The push-button switches 112a through 112n are preferable when the viewer/listener 8 desires discontinuous signal processing (for example, when the viewer/listener 8 selects a desired concert hall to be reproduced in acoustic processing performed for providing an acoustic signal with an acoustic characteristic of a concert hall).

The slidable switch 113 is preferable when the viewer/listener 8 desires continuous signal processing (for example, when the viewer/listener 8 selects a desired position of the virtual sound source 95 to be reproduced in acoustic processing performed on an acoustic signal for causing the viewer/listener 8 to perceive as if the virtual sound source 95 was moved and thus the direction to the sound source and a distance between the sound source and the viewer/listener 8 were changed).

The rotary switch 114 can be used similarly to the bush-button switches 112a through 112n when the selected filter coefficient changes discontinuously at every defined angle, and can be used similarly to the slidable switch 113 when the selected filter coefficient changes continuously.

The filter coefficient selection section 3 having the above-described structure provides the viewer/listener 8 with a sound matching the image based on the correction command, and with a sound desired by the viewer/listener 8.

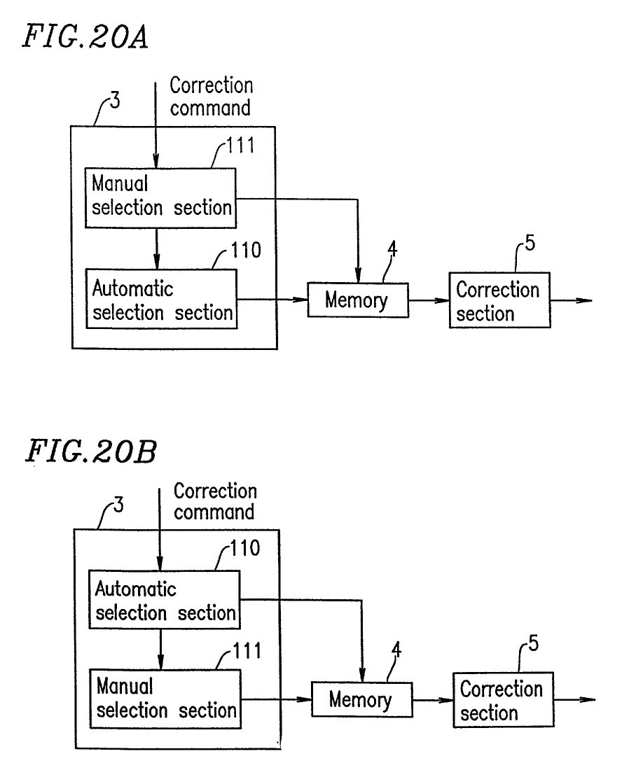

The structure of the filter coefficient selection section 3 is not limited to the structure shown in FIG. 18. Any structure which can appropriately select either signal processing desired by the viewer/listener 8 and signal processing based on a correction command may be used. For example, the filter coefficient selection section 3 may have a structure shown in FIG. 20A or a structure shown in FIG. 20B. In the case of the structures shown in FIGS. 20A and 20B, the manual selection section 111 is provided with a function of determining which of the selection results has a higher priority among the selection result by the manual selection section 111 and the selection result by the automatic selection section 110. By selecting at least one of the plurality of filter coefficients stored in the memory 4 based on the determination result, an effect similar to that of the filter coefficient selection section 3 shown in FIG. 18 is provided.

7. Method for Constructing a Reflection Structure

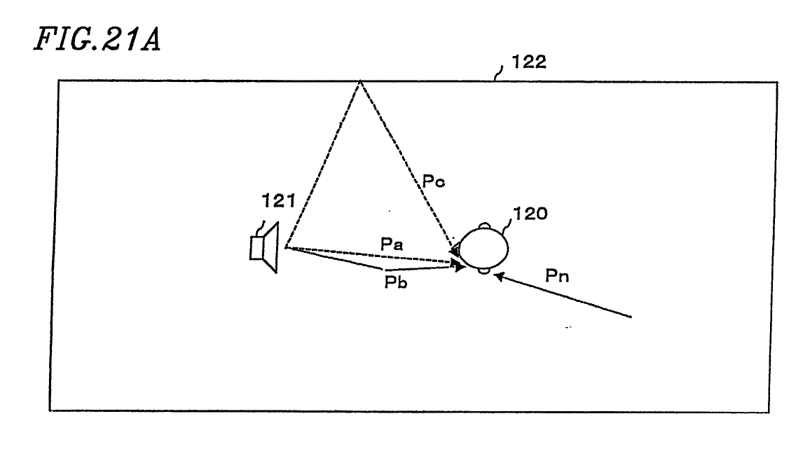

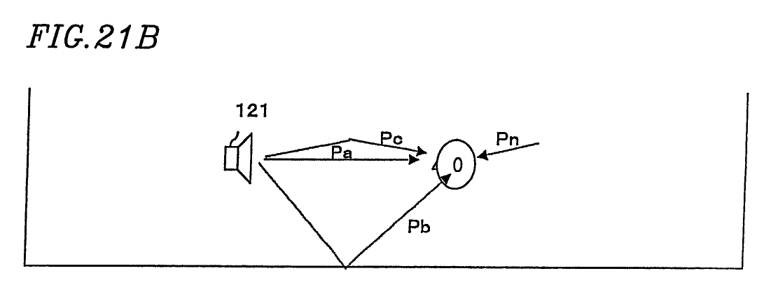

FIG. 21A is a plan view of a sound field 122, and FIG. 21B is a side view of the sound field 122.

As shown in FIGS. 21A and 21B, a sound source 121 and a viewer/listener 120 are located in the sound field 122. In FIGS. 21A and 21B, Pa represents a direct sound from the sound source 121 which directly reaches the viewer/listener 120. Pb represents a reflection which reaches the viewer/listener 120 after being reflected by a floor. Pc represents a reflection which reaches the viewer/listener 120 after being reflected by a side wall. Pn represents a reflection which reaches the viewer/listener 120 after being reflected a plurality of times.

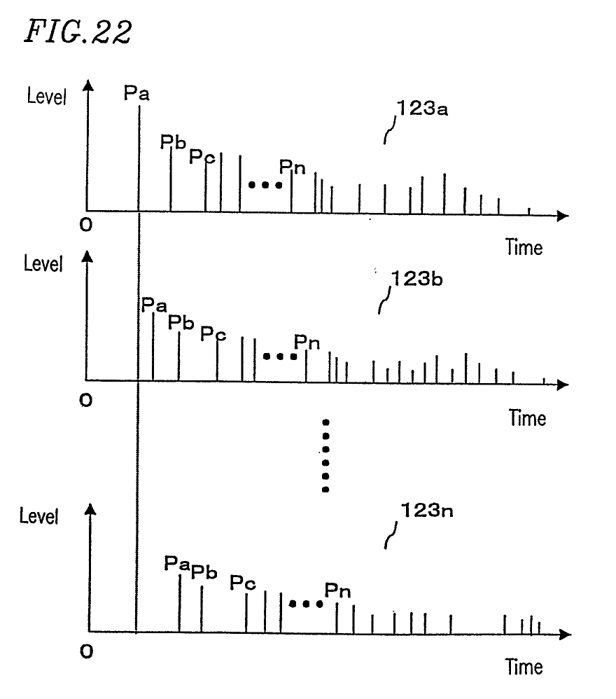

FIG. 22 shows reflection structures 123a through 123n obtained at the position of the left ear of the viewer/listener 120 in the sound field 122.

A sound emitted from the sound source 121 is divided into a direct sound Pa directly reaching the viewer/listener 120 and reflections Pb through Pn reaching the viewer/listener 120 after being reflected by walls surrounding the sound field 122 (including the floor or side walls).

A time period required for the sound emitted from the sound source 121 to reach the viewer/listener 120 is in proportion to the length of the path of the sound. Therefore, in the sound field 122 shown in FIGS. 21A and 21B, the sound reaches the viewer/listener 120 in the order of the direct sound Pa, the reflection Pb, the reflection Pc and the reflection Pn.

The reflection structure 123a shows the relationship between the levels of the direct sound Pa and the reflections Pb through Pn emitted from the sound source 121 and the time periods required for the sounds Pa through Pn to reach the left ear of the viewer/listener 120. The vertical axis represents the level, and the horizontal axis represents the time. Time 0 represents the time when the sound is emitted from the sound source 121. Accordingly, the reflection structure 123a shows the sounds Pa through Pn in the order of reaching the left ear of the viewer/listener 120. Namely, the direct sound Pa is shown at a position closest to the time 0, and then the sound Pb, the sound Pc and the sound Pn are shown in this order. Regarding the level of the sound at the viewer/listener 120, the direct sound Pa is highest since the direct sound Pa is distance-attenuated least and is not reflection-attenuated. The reflections Pb through Pn are attenuated more as the length of the pass is longer and are also attenuated by being reflected. Therefore, the reflections Pb through Pn are shown with gradually lower levels. The reflection Pn has the lowest level among the reflections Pb through Pn.

As described above, the reflection structure 123a shows the relationship between the levels of the sounds emitted from the sound source 121 and the time periods required for the sounds to reach the left ear of the viewer/listener 120 in the sound field 122. In a similar manner, a reflection structure, showing the relationship between the levels of the sounds emitted from the sound source 121 and the time periods required for the sounds to reach the right ear of the viewer/listener 120 in the sound field 122, can be obtained. By correcting the acoustic signal AS using the filter coefficient representing these reflection structures, the sound field 122 can be simulated.

The reflection structures 123b through 123n show the relationship between the levels of the direct sound Pa and the reflections Pb through Pn emitted from the sound source 121 and the time periods required for the sounds Pa through Pn to reach the left ear of the viewer/listener 120 when the distance from the sound source 121 to the viewer/listener 120 gradually increases. (Neither the direction nor the height of the sound source 121 with respect to the viewer/listener 120 is changed.)

In the reflection structure 123b, the distance between the sound source 121 and the viewer/listener 120 is longer than that of the reflection structure 123a. Therefore, the time period required for the direct sound Pa to reach the left ear of the viewer/listener 120 is longer in the reflection structure 123b than in the reflection structure 123a. Similarly, in the reflection structure 123n, the distance between the sound source 121 and the viewer/listener 120 is longer than that of the reflection structure 123b. Therefore, the time period required for the direct sound Pa to reach the left ear of the viewer/listener 120 is longer in the reflection structure 123n than in the reflection structure 123b.

As the distance between the sound source 121 and the viewer/listener 120 becomes longer, the amount of distance attenuation becomes larger. Therefore, the levels of the sounds Pa through Pn are lower in the reflection structure 123b than in the reflection structure 123a. Similarly, the levels of the sounds Pa through Pn are lower in the reflection structure 123n than in the reflection structure 123b.

The time periods required for the reflections Pb through Pn are also longer in the reflection structures 123b through 123n than in the reflection structure 123a. The level of the reflections Pb through Pn are lower in the reflection structures 123b through 123n than in the reflection structure 123a. However, in the reflection structures 123b through 123n, the reduction amount in the reflections Pb through Pn is smaller than the reduction amount in the direct sound Pa. The reason for this is as follows. Since the paths of the reflections Pb through Pn are longer than the path of the direct sound Pa, the ratio of the change in the path length due to the movement of the sound source 121 with respect to the total path length is smaller in the case of the reflections Pb through Pn than in the case of the direct sound Pa.

As in the case of the reflection structure 123a, the reflection structures 123b through 123n show the relationship between the levels of the sounds emitted from the sound source 121 and the time periods required for the sounds to reach the left ear of the viewer/listener 120 in the sound field 122.

In a similar manner, reflection structures, showing the relationship between the levels of the sounds emitted from the sound source 121 and the time periods required for the sounds to reach the right ear of the viewer/listener 120 in the sound field 122, can be obtained. By correcting the acoustic signal AS using the filter coefficient representing these reflection structures, the sound field 122 can be simulated.

In addition, by selecting the plurality of reflection structures 123a through 123n for use, the viewer/listener 120 can listen to the sound at the sound source at a position desired by the viewer/listener 120 in the sound field 122.

In the above example, there is only one sound source 121 provided. When there are a plurality of sound sources also, the sound field can be simulated by obtaining the reflection structure in a similar manner. In the above example, the direction from which the sound is transferred is not defined for obtaining the reflection structure. The simulation precision of the sound field can be improved by obtaining the reflection structure while the direction from which the sound is transferred is defined.

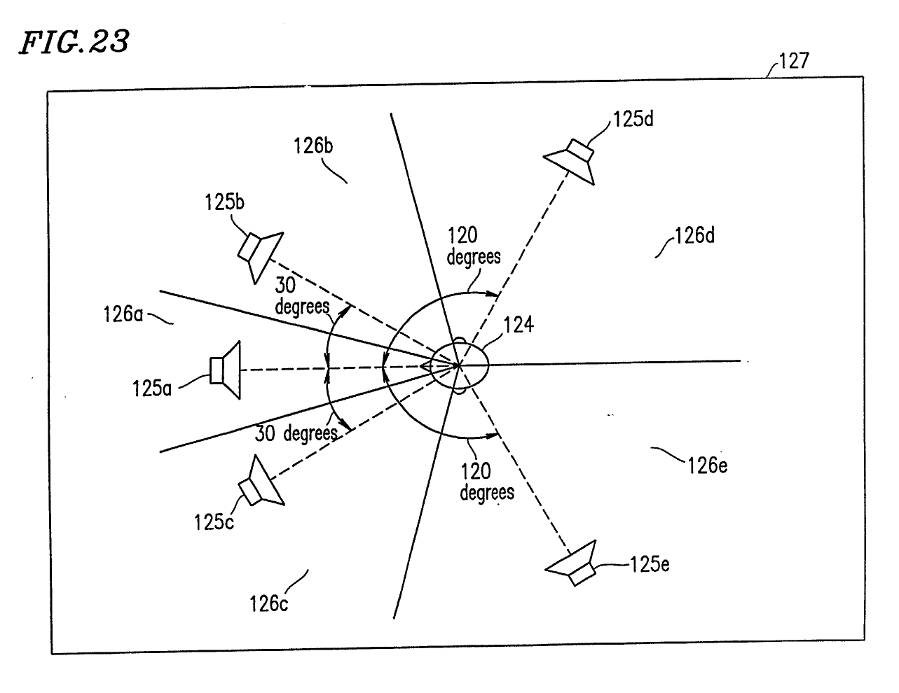

With reference to FIG. 23, a method for constructing a reflection structure from a sound field 127 including five speakers will be described.

FIG. 23 is a plan view of the sound field 127 in which five sound sources are located.

As shown in FIG. 23, sound sources 125a through 125e and a viewer/listener 124 are located in the sound field 127. The sound sources 125a through 125e are located so as to surround the viewer/listener 124 at the same distance from the viewer/listener 124. In FIG. 23, reference numerals 126a through 126e each represent an area (or a range) defined by lines dividing angles made by each two adjacent sound sources with the viewer/listener 124.

The sound sources 125a through 125e are located so as to form a general small-scale surround sound source. The sound source 125a is for a center channel to be provided exactly in front of the viewer/listener 124. The sound source 125b is for a front right channel to be provided to the front right of the viewer/listener 124. The sound source 125c is for a front left channel to be provided to the front left of the viewer/listener 124. The sound source 125d is for a rear right channel to be provided to the rear right of the viewer/listener 124. The sound source 125e is for a rear left channel to be provided to the rear left of the viewer/listener 124.

The angle made by the sound sources 125a and 125b or 125c with the viewer/listener 124 is 30 degrees. The angle made by the sound sources 125a and 125d or 125e with the viewer/listener 124 is 120 degrees. The sound sources 125a through 125e are respectively located in the areas 126a through 126e. The area 126a expands to 30 degrees from the viewer/listener 124. The areas 126b and 126c each expand to 60 degrees from the viewer/listener 124. The areas 126d and 126e each expand to 105 degrees from the viewer/listener 124.

Hereinafter, an example of reproducing the sound field 122 shown in FIGS. 21A and 21B with the sound field 127 will be described. In the sound field 122, the sound emitted from the sound source 121 reaches the viewer/listener 120 through various paths. Accordingly, the viewer/listener 120 listen to the direct sound transferred from direction of the sound source 121 and reflections transferred in various directions. In order to reproduce such a sound field 122 with the sound field 127, a reflection structure representing the sound reaching the position of the left and right ears of the viewer/listener 120 in the sound field 122 is obtained for each direction from which the sound is transferred, and the reflection structure is used for reproduction.

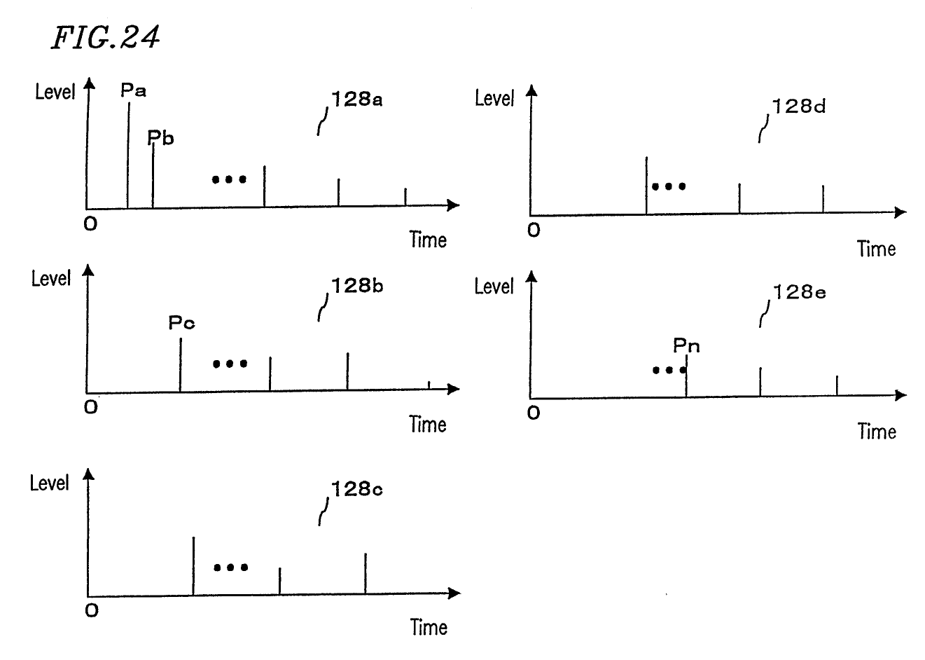

FIG. 24 shows reflection structures obtained for the direction from which the sound is transferred in each of the areas 126a through 126e. Reference numerals 128a through 128e respectively show the reflection structures obtained for the areas 126a through 126e.

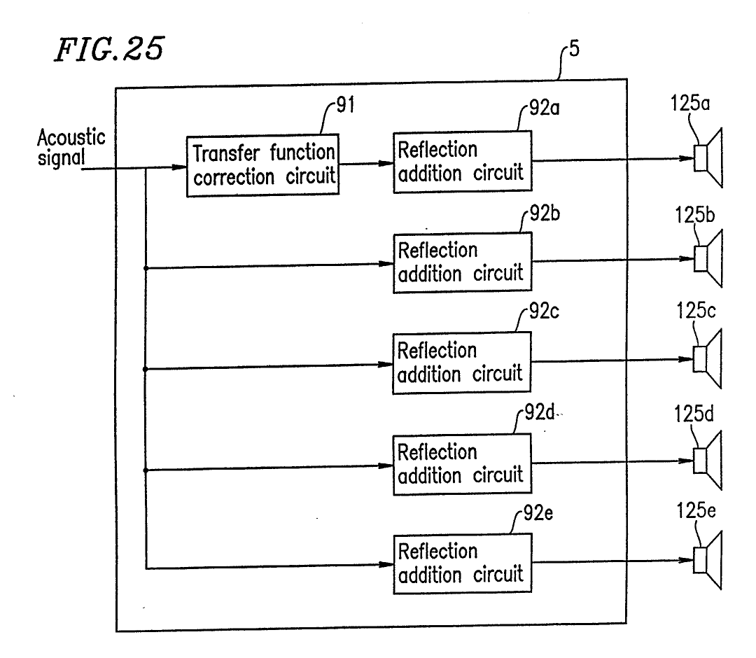

FIG. 25 shows an exemplary structure of the correction section 5 for reproducing the sound field 122 using the reflection structures 128a through 128e.

The correction section 5 includes a transfer function correction circuit 91 and reflection addition circuits 92a though 92e. The transfer function correction circuit 91 is adjusted so that an acoustic characteristic of the sound emitted from the sound source 125a when reaching the viewer/listener 124 is equal to the acoustic characteristic of the sound emitted from the sound source 121 when reaching the viewer/listener 120. The reflection addition circuits 92a through 92e are respectively adjusted so as to generate, from an input signal, reflections which have identical structures with the reflection structures 128a through 128e and output the generated reflections.

By inputting the outputs from the reflection addition circuits 92a through 92e to the sound sources 125a through 125e, the sound field 122 can be simulated at a higher level of precision. The reasons for this are because (i) the reflection structures 128a through 128e allow the levels of the reflections and the time periods required for the reflections to reach the viewer/listener 124 to be reproduced, and (ii) the sound source 125a through 125e allow the directions from which the reflections are transferred to be reproduced.

Even when the transfer function correction circuit 91 is eliminated from the structure shown in FIG. 25, an effect similar to that described above is provided. The transfer function correction circuit 91 need not necessarily provided for the signal input to the sound source 125a.

In FIGS. 23 through 25, the sound field 122 is reproduced with the five sound source 125a through 125e. Five sound sources are not necessary required. For example, the sound field 122 can be reproduced using the headphones 6. This will be described below.

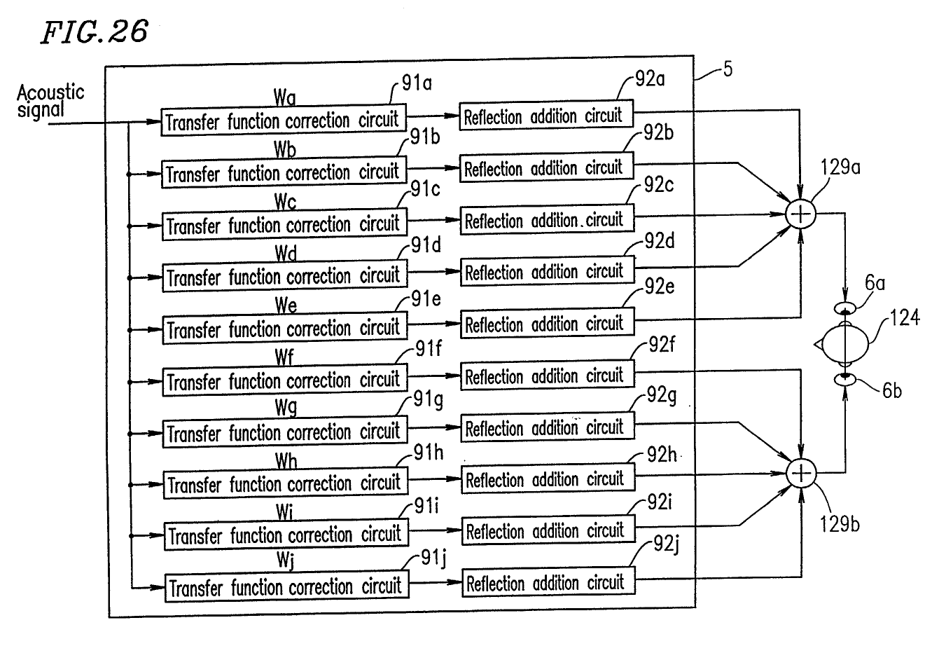

FIG. 26 shows an exemplary structure of the correction section 5 for reproducing the sound field 122 using the headphones 6.

As shown in FIG. 26, the correction section 5 includes transfer function correction circuits 91a through 91j for correcting an acoustic characteristic of an acoustic signal AS, reflection addition circuits 92a through 92j respectively for adding reflections to the outputs from the transfer function correction circuits 91a through 91j, an adder 129a for adding the outputs from the reflection addition circuits 92a through 92e, and an adder 129b for adding the outputs from the reflection addition circuits 92f through 92j. The output from the adder 129a is input to the right channel speaker 6a of the headphones 6. The output from the adder 129b is input to the left channel speaker 6b of the headphones 6. In FIG. 26, Wa through Wj represent transfer functions of the transfer function correction circuits 91a through 91j.

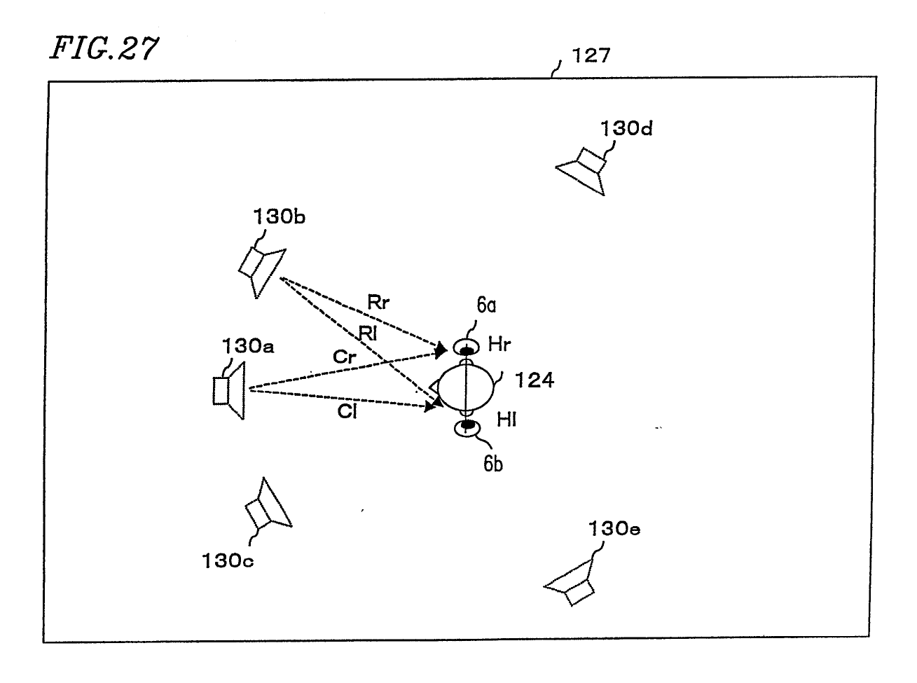

FIG. 27 shows a sound field 127 reproduced by the correction section 5 shown in FIG. 26. Virtual sound sources 130a through 130e and a viewer/listener 124 are located in the sound field 127. The positions of the virtual sound sources 130a through 130e are the same as the positions of the sound sources 125a through 125e shown in FIG. 23.

In FIG. 27, Cr represents a transfer function from the sound source 125a to the right ear of the viewer/listener 124 when the viewer/listener 124 does not wear the headphones 6. Cl represents a transfer function from the sound source 125a to the left ear of the viewer/listener 124 when the viewer/listener 124 does not wear the headphones 6. Hr represents a transfer function from the right channel speaker 6a of the headphones 6 to the right ear of the viewer/listener 124. Hl represents a transfer function from the left channel speaker 6b of the headphones 6 to the left ear of the viewer/listener 124.

The case of reproducing the sound from the sound source 125a by the headphones 6 will be described. Here, a transfer function of the transfer function correction circuit 91a is Wa, and a transfer function of the transfer function correction circuit 91f is Wf. A transfer function from the right channel speaker 6a of the headphones 6 to the right ear of the viewer/listener 124 is Hr, and a transfer function from the left channel speaker 6b of the headphones 6 to the left ear of the viewer/listener 124 is Hl. In this case, expression (5) is formed.

Cr=Wa·Hr

Cl=Wf·Hl ...expression (5)

By using Wa and Wf obtained from expression (5) respectively as the transfer functions of the transfer function correction circuits 91a and 91f, the sound from the sound source 125a can be reproduced by the headphones 6. Namely, while the sound is actually emitted from the headphones 6, the viewer/listener 124 can perceive the sound as if it was emitted from the virtual sound source 125a.

Based on expression (5), the transfer function Wa of the transfer function correction circuit 91a and the transfer function Wf of the transfer function correction circuit 91f are given by expression (6).

Wa=Cr/Hr

Wf=Cl/Hl ...expression (6)

The reflection addition circuit 92f adds, to the output from the transfer function correction circuit 91f, a reflection having a reflection structure 128a obtained by extracting only a reflection from the direction of the range 126a represented by the sound source 125a to the left ear of the viewer/listener 124. Similarly, the reflection addition circuit 92a adds, to the output from the transfer function correction circuit 91a, a reflection having a reflection structure (not shown) obtained by extracting only a reflection from the direction of the range 126a represented by the sound source 125a to the right ear of the viewer/listener 124. The reflection structure obtained by extracting only the reflection reaching the right ear of the viewer/listener 124 can be formed in a method similar to the method of obtaining the reflection structure 128a obtained by extracting only the reflection reaching the left ear of the viewer/listener 124. As a result, the viewer/listener 124 perceives the presence of the virtual sound source 130a and also receives the sound accurately simulating the direct sound and the reflections from the sound source 125a through the headphones 6.

Similarly, the case of reproducing the sound from the sound source 125b by the headphones 6 will be described. Here, a transfer function from the sound source 125b to the right ear of the viewer/listener 124 when the viewer/listener 124 does not wear the headphones 6 is Rr, and a transfer function from the sound source 125b to the left ear of the viewer/listener 124 when the viewer/listener 124 does not wear the headphones 6 is Rl. In this case, expression (7) is formed.

Rr=Wb·Hr

Rl=Wg·Hl ...expression (7)

By using Wb and Wg obtained from expression (7) respectively as the transfer functions of the transfer function correction circuits 91b and 91g, the sound from the sound source 125b can be reproduced by the headphones 6. Namely, while the sound is actually emitted from the headphones 6, the viewer/listener 124 can perceive the sound as if it was emitted from the virtual sound source 125b.

Based on expression (7), the transfer function Wb of the transfer function correction circuit 91b and the transfer function Wg of the transfer function correction circuit 91g are given by expression (8).

Wb=Rr/Hr

Wg=Rl/Hl expression (8)

The reflection addition circuit 92g adds, to the output from the transfer function correction circuit 91g, a reflection having a reflection structure 128b obtained by extracting only a reflection from the direction of the range 126b represented by the sound source 125b to the left ear of the viewer/listener 124. Similarly, the reflection addition circuit 92b adds, to the output from the transfer function correction circuit 91b, a reflection having a reflection structure (not shown) obtained by extracting only a reflection from the direction of the range 126b represented by the sound source 125b to the right ear of the viewer/listener 124. The reflection structure obtained by extracting only the reflection reaching the right ear of the viewer/listener 124 can be formed in a method similar to the method of obtaining the reflection structure 128b obtained by extracting only the reflection reaching the left ear of the viewer/listener 124. As a result, the viewer/listener 124 perceives the presence of the virtual sound source 130b and also receives the sound accurately simulating the direct sound and the reflections from the sound source 125b through the headphones 6.

Similarly, the viewer/listener 124 perceives the presence of the virtual sound source 130c by the transfer function correction circuits 91c and 91h and the reflection addition circuits 92a and 92h. The viewer/listener 124 perceives the presence of the virtual sound source 130d by the transfer function correction circuits 91d and 91i and the reflection addition circuits 92d and 92i. The viewer/listener 124 perceives the presence of the virtual sound source 130e by the transfer function correction circuits 91e and 91j and the reflection addition circuits 92e and 92j.

As described above, the sound field 127 having the sound sources 125a through 125e located therein can be reproduced using the correction section 5 shown in FIG. 26. As a result, the sound field 122 which can be reproduced with the sound field 127 can also be reproduced.

In this example, the sound is received using the headphones. The present invention is not limited to this. For example, even when the sound is received by a combination of two speakers, an effect similar to that described above is provided by combining the transfer function correction circuits and the reflection addition circuits.

In this example, one acoustic signal is input to the correction section 5. The number of signals input to the correction section 5 is not limited to one. For example, an acoustic signal input to the correction section 5 can be 5.1-channel surround acoustic signals by Dolby Surround.

The transfer function correction circuits 91a through 91j and the reflection addition circuits 91a through 92j need not be respectively connected in the order shown in FIG. 26. Even when the transfer function correction circuits 91a through 91 and the reflection addition circuits 92a through 92j are respectively connected in an opposite order to the order shown in FIG. 26, an effect similar to that described above is provided.

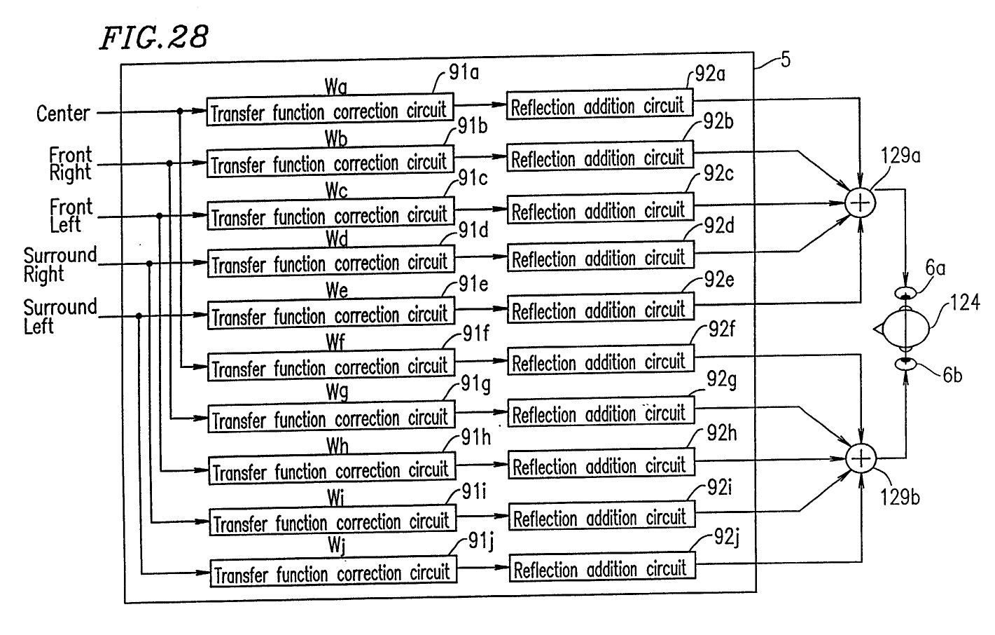

FIG. 28 shows an exemplary structure of the correction section 5 in the case where 5.1-ch acoustic signals by Dolby Surround are input to the correction section 5.

In the example shown in FIG. 28, a center channel signal (Center) emitted from the sound source provided exactly in front of the viewer/listener 124, a right channel signal (Front Right) provided to the front right of the viewer/listener 124, a left channel signal (Front Left) provided to the front left of the viewer/listener 124, a surround right channel signal (Surround Right) provided to the rear right of the viewer/listener 124, and a surround left channel signal (Surround Left) provided to the rear left of the viewer/listener 124 are input to the correction section 5.

As shown in FIG. 28, the signals input to the correction section 5 are corrected using the transfer function correction circuits 91a through 91j and the reflection addition circuits 92a through 92j. Thus, while the sound is actually emitted from the headphones 6, the viewer/listener 124 can perceive the sound as if it was multiple-channel signals emitted from the virtual sound sources 130a through 130e.

The reflection structures used by the reflection addition circuits 92a through 92j are not limited to the reflection structures obtained in the sound field 122. For example, when a reflection structure obtained in a music hall desired by the viewer/listener 124 is used, favorable sounds can be provided to the viewer/listener 124.

The acoustic signals input to the correction section 5 are not limited to the center signal, the right channel signal, the left channel signal, the surround right signal, and the surround left signal. For example, a woofer channel signal, a surround back signal or other signals may be further input to the correction section 5. In this case, an effect similar to that described above is provided by correcting these signals using the transfer function correction circuits and the reflection addition circuits.

In this example, an acoustic signal which is input to the correction section 5 is input to the transfer function correction circuits, and the output signals from the transfer function correction circuits are input to the reflection addition circuits. Alternatively, an acoustic signal which is input to the correction section 5 may be input to the reflection addition circuits, and the output signals from the reflection addition circuits may be input to the transfer function correction circuits. In this case also, an effect similar to that described above is provided.

The areas 126a through 126e defining the directions from which the reflections are transferred are not limited to the above-defined areas. The definition of the areas 126a through 126e may be changed in accordance with the sound field or the content of the acoustic signal.

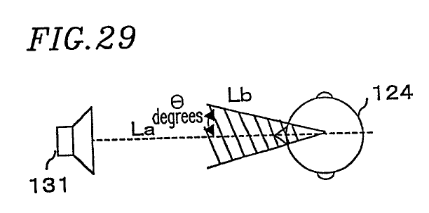

For example, the area may be defined as shown in FIG. 29. In FIG. 29, line La connects the center position of the head of the viewer/listener 124 and the center position of a sound source 131. Line Lb makes an angle of θ degrees with line La. An area which is obtained by rotating line Lb axis-symmetrically with respect to line La (the hatched area in FIG. 29) may define the direction from which the reflection is transferred when generating a reflection structure used by the reflection addition circuits. As the angle θ made by line La and line Lb increases, more and more reflection components are included in the reflection structure, but the direction from which the reflection is transferred obtained by the transfer function correction circuits and the reflection addition circuits becomes different from the direction in the sound field to be simulated, resulting in the position of the virtual sound source becoming more ambiguous. As the angle θ made by line La and line Lb decreases, less and less reflection components are included in the reflection structure, but the direction from which the reflection is transferred obtained by the transfer function correction circuits and the reflection addition circuits becomes closer to the direction in the sound field to be simulated, resulting in the position of the virtual sound source becoming clearer. As the angle θ made by line La and line Lb, 15 degrees is preferable. The reason for this is because the features of the face and ears of the viewer/listener with respect to the sound changes in accordance with the direction from which the sound is transferred, and thus the characteristics of the sound received by the viewer/listener change.

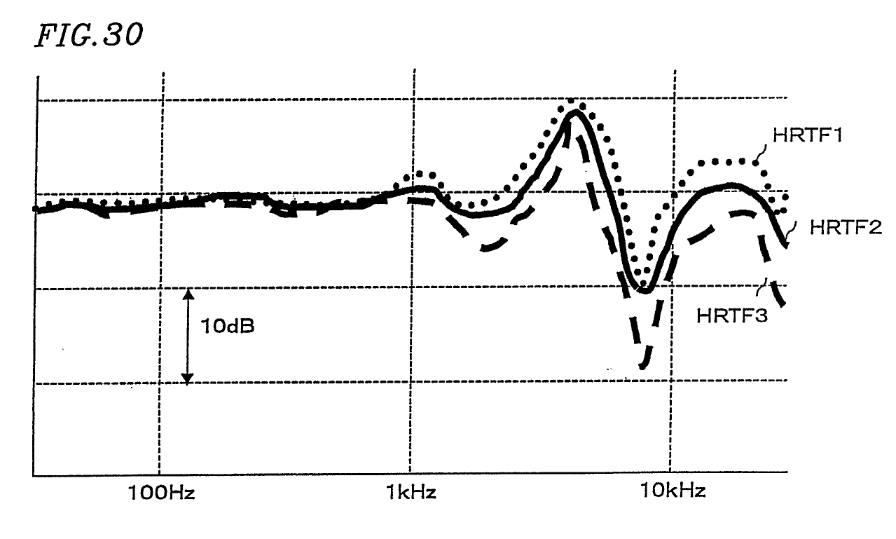

FIG. 30 shows the results of measurement of a head-related transfer function from the sound source to the right ear of a subject. The measurement was performed in an anechoic chamber. In FIG. 30, HRTF1 represents a head-related transfer function when one sound source is provided exactly in front of the subject. HRTF2 represents a head-related transfer function when one sound source is provided to the front left of the subject, at 15 degrees with respect to the direction exactly in front of the subject. HRTF3 represents a head-related transfer function when one sound source is provided to the front left of the subject, at 30 degrees with respect to the direction exactly in front of the subject.

In FIG. 30, the levels of the sounds are not very different in a frequency range of 1 kHz or lower. The difference between the levels of the sounds increases from 1 kHz. Especially, HRTF1 and HRTF3 have a maximum of about 10 dB. The difference between HRTF1 and HRTF2 is about 3 dB even at the maximum.

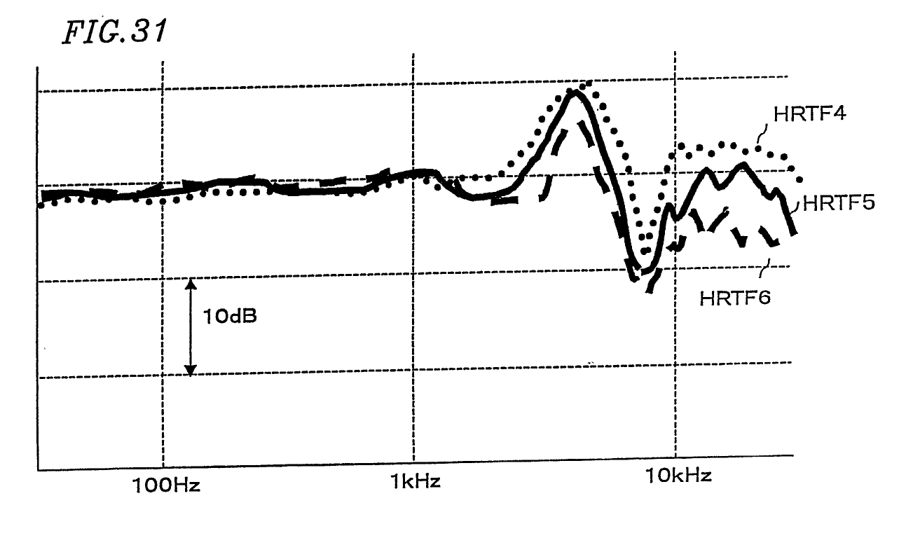

FIG. 31 shows the results of measurement of a head-related transfer function from the sound source to the right ear of a different subject. The measuring conditions, such as the position of the sound source and the like in FIG. 31 are the same from those of FIG. 30 except for the subject. In FIG. 31, HRTF4 represents a head-related transfer function when one sound source is provided exactly in front of the subject. HRTF5 represents a head-related transfer function when one sound source is provided to the front left of the subject, at 15 degrees with respect to the direction exactly in front of the subject. HRTF6 represents a head-related transfer function when one sound source is provided to the front left of the subject, at 30 degrees with respect to the direction exactly in front of the subject.

A comparison between HRTF1 (FIG. 30) and HRTF4 (FIG. 31), between HRTF2 (FIG. 30) and HRTF5 (FIG. 31), and between HRTF3 (FIG. 30) and HRTF6 (FIG. 31) shows the following. The measurement results in FIGS. 30 and 31 are not much different in a frequency range of about 8 kHz (a deep dip) or lower, and the measurement results in FIGS. 30 and 31 are significantly different in a frequency range of above 8 kHz. This indicates that the characteristics of the subject greatly influences the head-related transfer function in the frequency range of above 8 kHz. In the frequency range of 8 kHz or lower, the head-related transfer functions of different subjects are similar so long as the direction of the sound source is the same. Therefore, when a sound field is simulated for a great variety of people in consideration of the direction from which the sound is transferred, using the transfer function correction circuits and the reflection addition circuits, the characteristics of the sound field can be simulated in the frequency range of 8 kHz or lower. In the frequency range of 8 kHz or lower, the head-related transfer function does not significantly change even when the direction of the sound source is different by 15 degrees.

When the angle θ made by line La and line Lb in FIG. 29 is 15 degrees or less, the transfer function correction circuits are preferably adjusted so as to have a transfer function from the sound source 131 to the viewer/listener 124, and the reflection addition circuits are preferably adjusted so as to have a reflection structure of a reflection transferred in the hatched area in FIG. 29. In this manner, a reflection structure including a larger number of reflections can be obtained despite that the position of the virtual sound source is clear. As a result, the simulation precision of the sound field is improved.

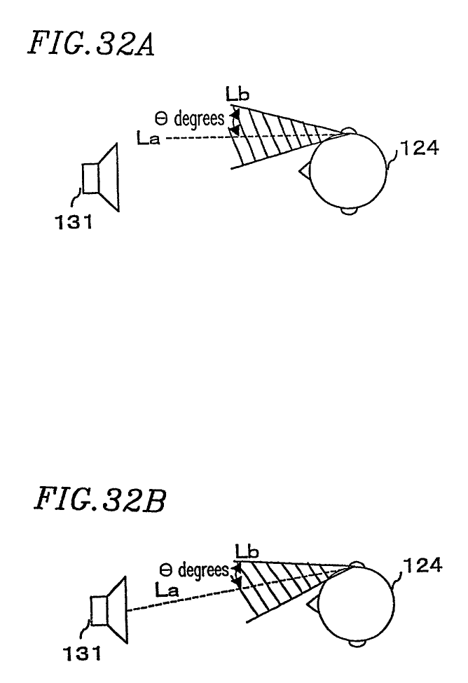

In this example, each of the areas 126a through 126e, defining the direction from which the reflections are transferred, is obtained by rotating line Lb axis-symmetrically with respect to line La (the hatched area in FIG. 29). In FIG. 29, line La connects the center position of the head of the viewer/listener 124 and the center position of a sound source 131. Line Lb makes an angle of θ degrees with line La. Alternatively, each of the areas 126a through 126e may be defined as shown in FIG. 32A or FIG. 32B. In FIG. 32A, line La is a line extending from the right ear of the viewer/listener 124 in the forward direction of the viewer/listener 124. Line Lb makes an angle of θ with line La. Each of the areas 126a through 126e may be defined as an area obtained by rotating line Lb axis-symmetrically with respect to line La (the hatched area in FIG. 32A). In FIG. 32B, line La connects the right ear of the viewer/listener 124 and the center position of the sound source 131. Line Lb makes an angle of θ with line La. Each of the areas 126a through 126e may be defined as an area obtained by rotating line Lb axis-symmetrically with respect to line La (the hatched area in FIG. 32B).

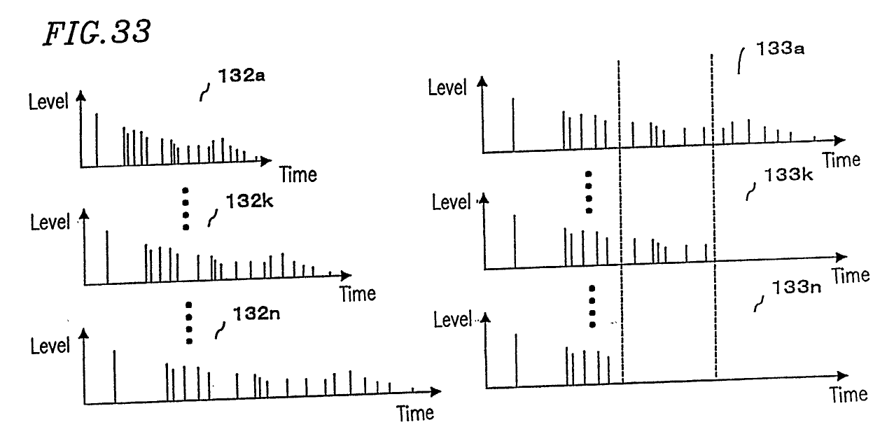

In this example, the method is described in which a plurality of reflection structures (for example, reflection structures 123a through 123n) are selectively used in order to provide the viewer/listener with the perception of distance desired by the viewer/listener. The reflection structures need not be loyally obtained from the sound field to be simulated. For example, as shown in FIG. 33, the time axis of a reflection structure 132a for providing the perception of the shortest distance may be extended to form a reflection structure 132k or 132n for providing perception of a longer distance. Alternatively, the time axis of a reflection structure 133a for providing the perception of the longest distance may be divided or partially deleted based on a certain time width to form a reflection structure 133k or 133n for providing perception of a shorter distance.

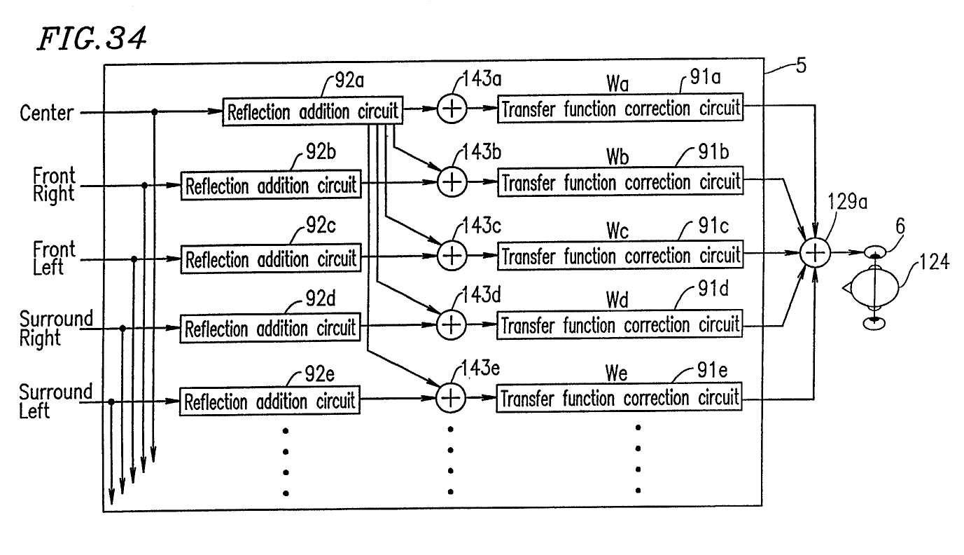

FIG. 34 shows another exemplary structure of the correction section 5 in the case where 5.1-ch acoustic signals by Dolby Surround are input to the correction section 5. In FIG. 34, identical elements previously discussed with respect to FIG. 28 bear identical reference numerals and the detailed descriptions thereof will be omitted.

In the example shown in FIG. 34, the correction section 5 includes adders 143a through 143e. The adders 143a through 143e are respectively used to input the output from the reflection addition circuit 92a to the transfer function correction circuits 91a through 91e. The outputs from the transfer function correction circuits 91a through 91e are added by the adder 129a. The output from the adder 129a is input to the right channel speaker 6a of the headphones 6. In the structure of the correction section 5 shown in FIG. 34, the reflection sound of the center signal reaching the viewer/listener 124 from the directions of the virtual sound sources respectively represented by the transfer function correction circuits 91a through 91e is simulated at a significantly high level of precision.

FIG. 34 only shows elements for generating a signal to be input to the right channel speaker 6a of the headphones 6. A signal to be input to the left channel speaker of the headphones 6 can be generated in a similar manner. FIG. 34 shows an exemplary structure for simulating the reflection of the center signal highly precisely. The correction section 5 may have a structure so as to simulate, to a high precision, the reflections of another signal (the front right signal, the front left signal, the surround right or the surround left signal) in a similar manner.

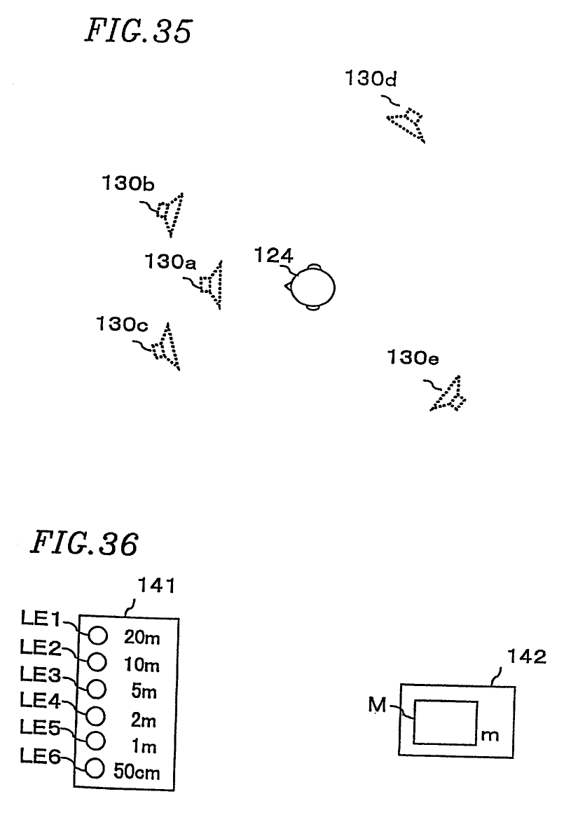

The structure of the correction section 5 described in this example can perform different types of signal processing using the transfer function correction circuits and the reflection addition circuits, for each of a plurality of acoustic signals which are input to the correction section 5 and/or for each of a plurality of virtual sound sources. As a result, as shown in FIG. 35, a plurality of virtual sound sources 130a through 130e may be provided at desired positions.

8. Display of the Distance Between a Virtual Sound Source and the Viewer/Listener

As described above, a virtual sound source is created by signal processing performed by the correction section 5. By changing the filter coefficient used by the correction section 5, the distance between the virtual sound source and the viewer/listener can be controlled. Accordingly, by monitoring the change in the filter coefficient used by the correction section 5, the distance between the virtual sound source and the viewer/listener can be displayed to the viewer/listener.

FIG. 36 shows examples of displaying the distance between the virtual sound source and the viewer/listener.

A display section 141 includes lamps LE1 through LE6. The display section 141 causes one of the lamps corresponding to the distance between the virtual sound source and the viewer/listener to light up in association with the change in the filter coefficient used by the correction section 5. Thus, the distance between the virtual sound source and the viewer/listener can be displayed to the viewer/listener.

A display section 142 includes a monitor M. The display section 142 numerically displays the distance between the virtual sound source and the viewer/listener in association with the change in the filter coefficient used by the correction section 5, so as to display the distance to the viewer/listener.

By providing the signal processing apparatus 1a (FIG. 1A) with the display section 141 or 142, the viewer/listener can visually perceive the distance between the virtual sound source and the viewer/listener as well as audibly.

In this example, the display section 141 includes six lamps. The number of lamps is not limited to six. The display section can display the distance between the virtual sound source and the viewer/listener in any form as long as the viewer/listener can perceive the distance.

A signal processing apparatus according to the present invention allows the correction method of an acoustic signal to be changed in accordance with the change in an image signal or an acoustic signal. Thus, the viewer/listener can receive, through a speaker or a headphones, a sound matching an image now displayed by an image display apparatus. As a result, the viewer/listener is prevented from experiencing an undesirable discrepancy in the relationship between the image and the sound.

A signal processing apparatus according to the present invention allows the correction method of an acoustic signal to be changed in accordance with the acoustic characteristic of the speaker or the headphones used by the viewer/listener or the acoustic characteristic based on the individual body features, for example, the shape of the ears and the face of the viewer/listener. As a result, a more favorable listening environment can be provided to the viewer/listener.

A signal processing apparatus according to the present invention prevents reproduction of an image signal, an acoustic signal or navigation data from being interrupted by reproduction of a filter coefficient requiring a larger capacity than the correction command.

A signal processing apparatus according to the present invention can reproduce acoustic signal correction data recorded on a recording medium without interrupting the image signal or the acoustic signal which is output from the reproduction apparatus.

A signal processing apparatus according to the present invention can allow the viewer/listener to perceive a plurality of virtual sound sources using a speaker or a headphones, and also can change the positions of the plurality of virtual sound sources. As a result, a sound field desired by the viewer/listener can be generated.

A signal processing apparatus according to the present invention can display the distance between the virtual sound source and the viewer/listener to the viewer/listener. Thus, the viewer/listener can visually perceive the distance as well as audibly.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A signal processing apparatus for processing an acoustic signal reproduced together with an image signal, the signal processing apparatus comprising:
a memory for storing a plurality of filter coefficients for correcting the acoustic signal;
a filter coefficient selection section for receiving a correction command, from outside the signal processing apparatus, for specifying a correction method for the acoustic signal and selecting at least one of the plurality of filter coefficients stored in the memory based on the correction command; and
a correction section for correcting the acoustic signal using the at least one filter coefficient selected by the filter coefficient selection section.

2. A signal processing apparatus according to claim 1, wherein the correction command is input to the signal processing apparatus by receiving of a broadcast signal or a communication signal.

3. A signal processing apparatus according to claim 1, wherein the correction command is recorded on a recording medium and is input to the signal processing apparatus by reproduction of the recording medium.

4. A signal processing apparatus according to claim 1, wherein the memory is arranged so as to receive at least one filter coefficient for correcting the acoustic signal from outside the signal processing apparatus, and to add the at least one filter coefficient received to the plurality of filter coefficients stored in the memory or to replace at least one of the plurality of filter coefficients stored in the memory with the at least one filter coefficient received.

5. A signal processing apparatus according to claim 4, wherein the at least one filter coefficient received is recorded on a recording medium and is input to the signal processing apparatus by reproduction of the recording medium.

6. A signal processing apparatus according to claim 5, further comprising a buffer memory for temporarily accumulating the image signal and the acoustic signal, wherein:
a speed at which the image signal and the acoustic signal are input to the buffer memory is higher than a speed at which the image signal and the acoustic signal are output from the buffer memory,
the at least one filter coefficient recorded on the recording medium is stored in the memory while the image signal and the acoustic signal are output from the buffer memory, and
a time period required for the image signal and the acoustic signal to be output from the buffer memory is equal to or longer than a time period for the at least one filter coefficient to be stored in the memory.

7. A signal processing apparatus according to claim 1, wherein:
the at least one filter coefficient selected includes at least one filter coefficient representing a transfer function showing an acoustic characteristic of a direct sound from a sound source to a viewer/listener, and
the correction section includes a transfer function correction circuit for correcting a transfer function of the acoustic signal in accordance with the at least one filter coefficient representing the transfer function.

8. A signal processing apparatus according to claim 1, wherein:
the at least one filter coefficient selected includes at least one filter coefficient representing a transfer function showing an acoustic characteristic of a direct sound from a sound source to a viewer/listener and at least one filter coefficient representing a reflection structure showing an acoustic characteristic of a reflection from the sound source to the viewer/listener, and
the correction section includes:
a transfer function correction circuit for correcting the transfer function of the acoustic signal in accordance with the at least one filter coefficient representing the transfer function,
a reflection addition circuit for adding a reflection to the acoustic signal in accordance with the at least one filter coefficient representing the reflection structure, and
an adder for adding an output from the transfer function correction circuit and an output from the reflection addition circuit.

9. A signal processing apparatus according to claim 1, wherein:
the at least one filter coefficient selected includes at least one filter coefficient representing a transfer function showing an acoustic characteristic of a direct sound from a sound source to a viewer/listener and at least one filter coefficient representing a reflection structure showing an acoustic characteristic of a reflection from the sound source to the viewer/listener, and
the correction section includes:
a transfer function correction circuit for correcting the transfer function of the acoustic signal in accordance with the at least one filter coefficient representing the transfer function, and
a reflection addition circuit for adding a reflection to an output of the transfer function correction circuit in accordance with the at least one filter coefficient representing the reflection structure.

10. A signal processing apparatus according to claim 1, wherein the filter coefficient selection section includes:
an automatic selection section for automatically selecting at least one of the plurality of filter coefficients stored in the memory based on the correction command, and
a manual selection section for manually selecting at least one of the plurality of filter coefficients stored in the memory.

11. A signal processing apparatus according to claim 8, wherein the at least one filter coefficient representing the reflection structure includes:
a first filter coefficient representing a reflection structure showing an acoustic characteristic of a reflection from the sound source to the viewer/listener when a distance between the sound source and the viewer/listener is a first distance, and
a second filter coefficient representing a reflection structure showing an acoustic characteristic of a reflection from the sound source to the viewer/listener when the distance between the sound source and the viewer/listener is a second distance which is different from the first distance.

12. A signal processing apparatus according to claim 9, wherein the at least one filter coefficient representing the reflection structure includes:
a first filter coefficient representing a reflection structure showing an acoustic characteristic of a reflection from the sound source to the viewer/listener when a distance between the sound source and the viewer/listener is a first distance, and
a second filter coefficient representing a reflect ion structure showing an acoustic characteristic of a reflection from the sound source to the viewer/listener when the distance between the sound source and the viewer/listener is a second distance which is different from the first distance.

13. A signal processing apparatus according to claim 8, wherein the at least one filter coefficient representing the reflection structure includes a third filter coefficient representing a reflection structure showing an acoustic characteristic of a reflection reaching the viewer/listener from a direction in a predetermined range.

14. A signal processing apparatus according to claim 9, wherein the at least one filter coefficient representing the reflection structure includes a third filter coefficient representing a reflection structure showing an acoustic characteristic of a reflection reaching the viewer/listener from a direction in a predetermined range.

15. A signal processing apparatus according to claim 13, wherein the predetermined range is defined by a first straight line connecting the sound source and a center of a head of the viewer/listener and a second straight line extending from the center of the head of the viewer/listener at an angle of 15 degrees or less from the first straight line.

16. A signal processing apparatus according to claim 14, wherein the predetermined range is defined by a first straight line connecting the sound source and a center of a head of the viewer/listener and a second straight line extending from the center of the head of the viewer/listener at an angle of 15 degrees or less from the first straight line.

17. A signal processing apparatus according to claim 1, wherein the acoustic signal includes multiple-channel acoustic signals, and the filter coefficient selection section selects a filter coefficient corresponding to each of the multiple-channel acoustic signals.

18. A signal processing apparatus according to claim 1, further comprising a display section for displaying a distance between a sound source and a viewer/listener.

19. A recording medium, comprising:
an acoustic data area for storing an acoustic signal;
an image data area for storing an image signal;
a navigation data area for storing navigation data showing locations of the acoustic data area and the image data area; and
an assisting data area for storing assisting data, wherein:
acoustic signal correction data is stored in at least one of the acoustic data area, the image data area, the navigation data area, and the assisting data area, and
the acoustic signal correction data includes at least one of a correction command for specifying a correction method for the acoustic signal and a filter coefficient for correcting the acoustic signal.

20. A recording medium according to claim 19, wherein the correction command is stored in at least one of the acoustic data area, the image data area, and the navigation data area, and the filter coefficient is stored in the assisting data area.

21. A recording medium according to claim 19, wherein the image data area stores at least one image pack, and the image pack includes the image signal and the acoustic signal correction data.

22. A recording medium according to claim 19, wherein the acoustic data area stores at least one acoustic pack, and the acoustic pack includes the acoustic signal and the acoustic signal correction data.

23. A recording medium according to claim 19, wherein the navigation data area stores at least one navigation pack, and the navigation pack includes the navigation data and the acoustic signal correction data.
